(19) United States
(12) Patent Application Publication
(10) Pub. No.: US 2024/0222483 A1
(43) Pub. Date: Jul. 4, 2024

(54) 2D NANORIBBONS UTILIZING SILICON SCAFFOLDING

(71) Applicant: Intel Corporation, Santa Clara, CA (US)

(72) Inventors: Carl H. Naylor, Portland, OR (US); Kirby Maxey, Hillsboro, OR (US); Kevin O’Brien, Portland, OR (US); Chelsey Dorow, Portland, OR (US); Sudarat Lee, Hillsboro, OR (US); Ashish Verma Penumatcha, Beaverton, OR (US); Uygar Avci, Portland, OR (US); Matthew Metz, Portland, OR (US); Scott B. Clendenning, Portland, OR (US); Chia-Ching Lin, Portland, OR (US); Ande Kitamura, Portland, OR (US); Mahmut Sami Kavrik, Eugene, OR (US)

(73) Assignee: Intel Corporation, Santa Clara, CA (US)

(21) Appl. No.: 18/091,211

(22) Filed: Dec. 29, 2022

(51) Int. Cl. H01L 29/76; H01L 21/02; H01L 29/06; H01L 29/24; H01L 29/423; H01L 29/66; H01L 29/775

(52) U.S. Cl. CPC H01L 29/7606; H01L 21/02568; H01L 21/0257; H01L 21/02603; H01L 21/0262; H01L 21/02645; H01L 29/0673; H01L 29/24; H01L 29/42392; H01L 29/66969; H01L 29/775

(57) ABSTRACT

A transistor structure includes a stack of nanoribbons spanning between terminals of the transistor. Ends of the nanoribbons include silicon, and channel regions between the ends include a transition metal and a chalcogen. A gate structure over the channel regions includes an insulator between the channel regions and a gate electrode material. Contact regions may be formed by modifying portions of the channel regions by adding a dopant to, or altering the crystal structure of, the channel regions. The transistor structure may be in an integrated circuit device.

### BACKGROUND

Performance and cost pressures drive a continuous and ever-increasing demand for denser, cheaper, and faster integrated circuit devices. To maintain the pace of increasing transistor density, device dimensions must continue shrinking. However, the performance of silicon transistors drops significantly at the nanometer scale. For example, silicon performance degrades at reduced body thicknesses as gate length decreases, e.g., below 7 nm. Improved materials may enable continued increases in transistor densities, clock speeds, and price efficiencies, but integration of improved materials may be hindered without the necessary infrastructures and processes.

New structures and methods are needed to leverage existing infrastructures and processes for rapidly integrating improved materials.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIG. 1 is a flow chart of methods for forming a transistor structure, including forming nanoribbons and channel layers of a two-dimensional (2D) material, in accordance with some embodiments;

FIGS. 2A, 2B, 2C, 2D, 2E, 2F, and 2G illustrate isometric views of a transistor structure with a stack of nanoribbons spanning between source and drain terminals, at various stages of manufacture, in accordance with some embodiments;

FIGS. 3A, 3B, 3C, 3D, 3E, 3F, 3G, and 3H illustrate isometric views of a transistor structure with a stack of nanoribbons spanning between source and drain terminals, at various stages of manufacture, in accordance with some embodiments;

FIGS. 4A, 4B, 4C, 4D, 4E, 4F, 4G, 4H, 4I, 4J, 4K, 4L, 4M, 4N, 4O, 4P, and 4Q illustrate isometric views of a transistor structure with a stack of nanoribbons spanning between source and drain terminals, at various stages of manufacture, in accordance with some embodiments;

FIGS. 5A, 5B, 5C, 5D, 5E, 5F, 5G, 5H, 5I, 5J, 5K, 5L, 5M, 5N, 5O, and 5P illustrate isometric views of a transistor structure with a stack of nanoribbons spanning between source and drain terminals, at various stages of manufacture, in accordance with some embodiments;

FIG. 6 illustrates a diagram of an example data server machine employing an integrated circuit (IC) device having 2D nanoribbons formed from a silicon scaffold, in accordance with some embodiments; and

FIG. 7 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve the performance of integrated circuit (IC) devices having two-dimensional (2D) nanoribbons by integrating improved materials with existing structures, for example, silicon scaffolding with nanoribbons between adjacent terminals. Silicon field effect transistors (FETs) with miniaturized channels, e.g., nanoribbons in ribbonFETs, suffer from degraded performance as body thicknesses are reduced with decreasing gate length (e.g., <7 nm). However, some 2D materials have promise as a replacement for silicon at the nanometer scale. These 2D materials are semiconducting and have high charge-carrier mobilities at the desired scale, and they may be quickly integrated if new methods can leverage existing silicon infrastructures and processes.

Scaffolding of silicon (or other convenient materials) may be formed using conventional methods. The scaffolding may allow for multiple nanoribbons in a vertical stack to span between source and drain terminals, e.g., as parallel channels in ribbonFETs. The exposed scaffolding material may be oxidized, and 2D materials may be deposited as thin films over, or in the place of, nanoribbons of oxidized, e.g., silicon. In some embodiments, 2D materials are deposited as channel layers that bypass oxidized nanoribbons in parallel with the new channel layers. In some embodiments, oxidized nanoribbons serve as templates for forming support layers that 2D materials are deposited on to form new nanoribbons.

In some embodiments, the 2D materials are transition metal dichalcogenides (TMD). TMD are compounds containing a transition metal and a chalcogen, and some TMD can be deposited as stable and semiconducting monolayers. In some embodiments, the transition metal is tungsten or molybdenum, and the chalcogen is sulfur or selenium. Thin channel layers can be formed with these TMD, and contact regions of the layers may be formed by modifying these regions by doping or by maintaining the composition but altering the crystalline structure of the TMD layer. Gate structures can be formed over the formed channel layers.

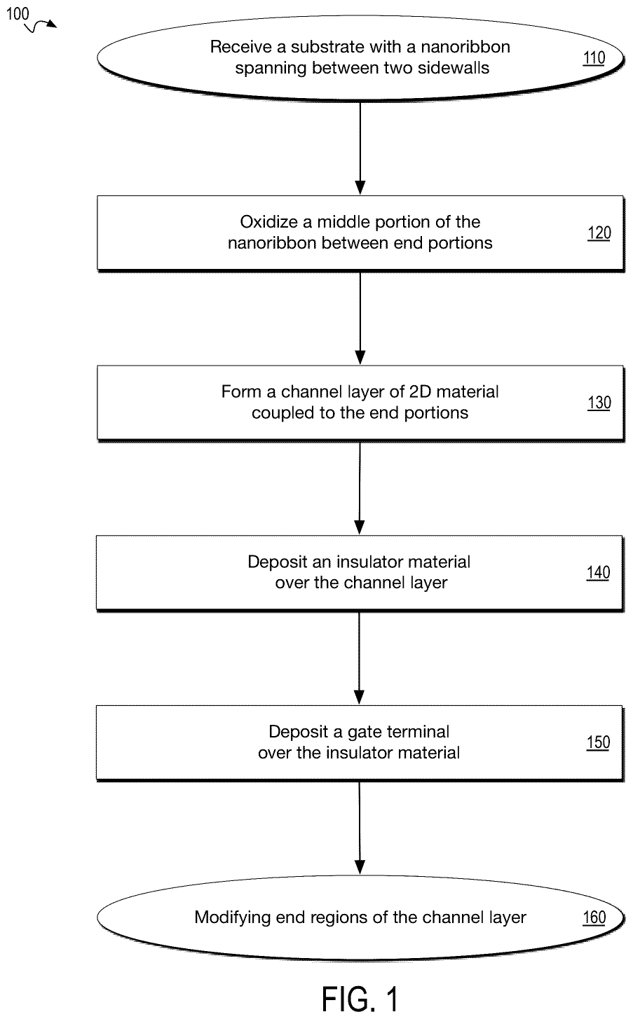

FIG. 1 is a flow chart of processes or methods 100 for forming a transistor structure, including forming nanoribbons and channel layers of a 2D material, in accordance with some embodiments. Methods 100 include operations 110-160. Some operations shown in FIG. 1 are optional. Additional operations may be included. FIG. 1 shows an example sequence, but the operations can be done in other orders as well, and some operations may be omitted. Some operations can also be performed multiple times before other operations are performed. For example, multiple channel layers may be formed before a gate terminal is coupled to the channel layers. Some operations may be included within other operations so that the number of operations illustrated FIG. 1 is not a limitation of the methods 100.

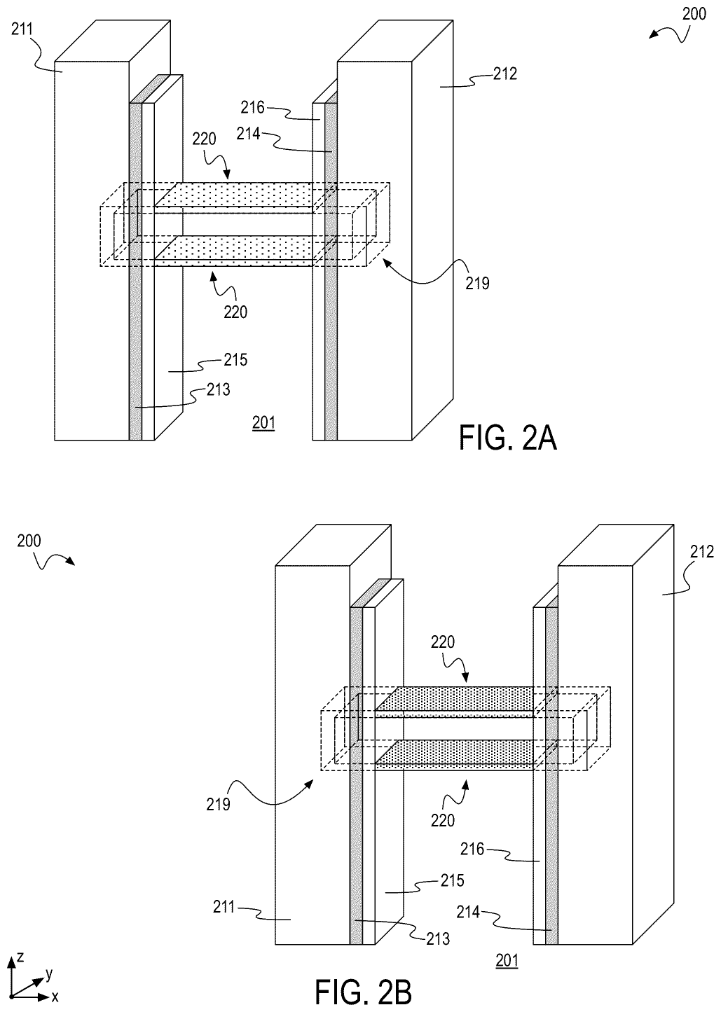

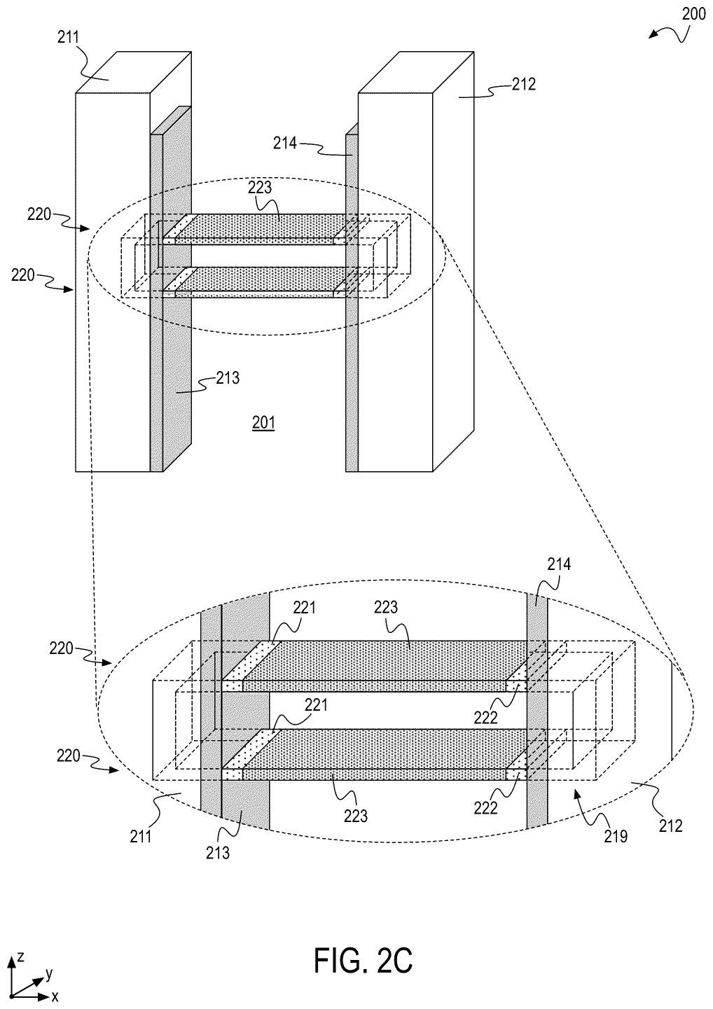

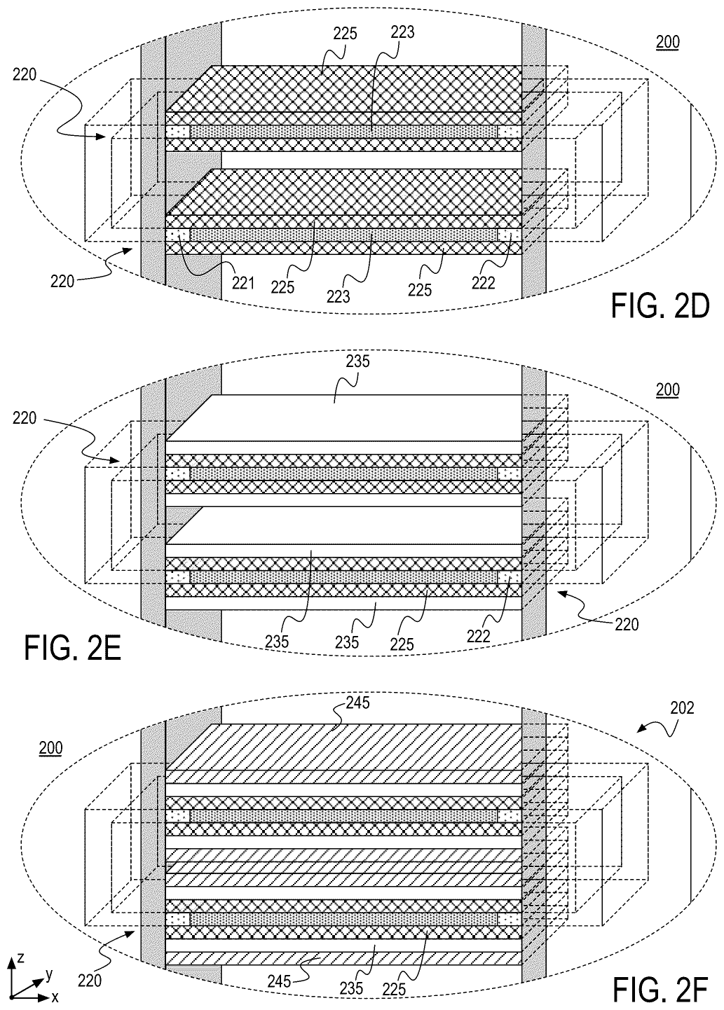

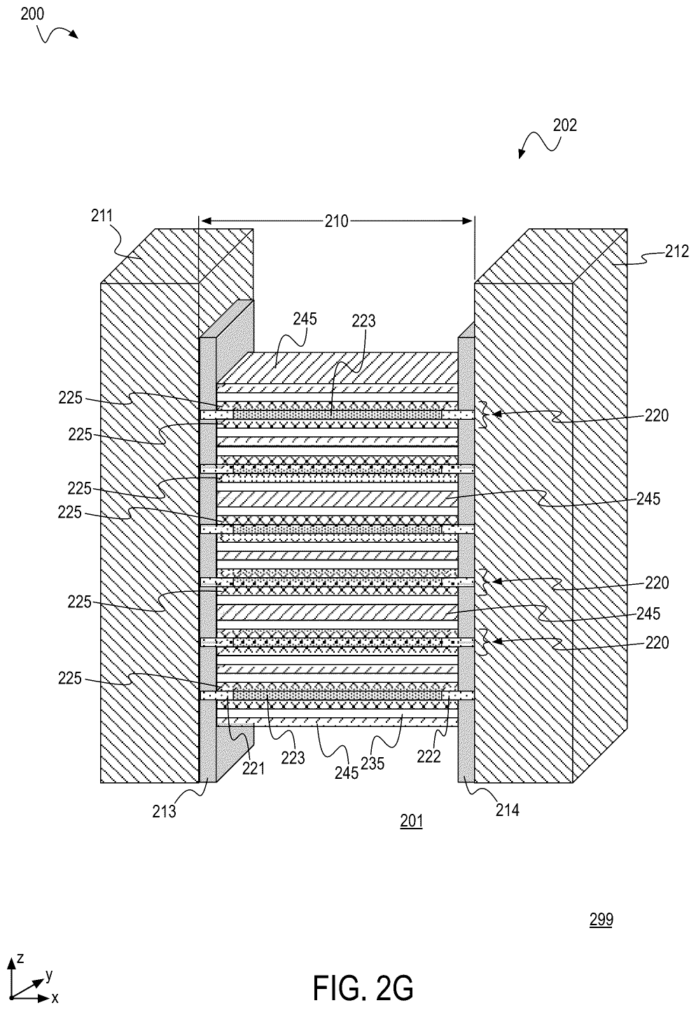

FIGS. 2A, 2B, 2C, 2D, 2E, and 2F illustrate isometric views of a transistor structure 202 with a stack of nanoribbons 220 spanning between source and drain terminals 211, 212, at various stages of manufacture, in accordance with some embodiments. Although structures may be referred to as a source or drain, e.g., terminal, in some examples, these labels are not restrictive and may be reversed in this and other embodiments.

Returning to FIG. 1, a structure is received at operation 110 having a nanoribbon spanning between first and second sidewalls, for example, of conducting material in terminals coupled by the nanoribbons. In some embodiments, the received structure is over a substrate in an IC die. The substrate may include a wafer or other piece of silicon or semiconductor or other, e.g., insulator, material. The substrate may include any suitable material or materials. In some examples, the substrate may include monocrystalline silicon (including silicon on insulator (SOI)), polycrystalline silicon, germanium, silicon germanium, a III-V alloy material (e.g., gallium arsenide), a silicon carbide (e.g., SiC), a sapphire (e.g., Al₂O₃), or any combination thereof. The substrate may also include semiconductor materials, metals, dielectrics, dopants, and other materials commonly found in semiconductor substrates.

The nanoribbon may include silicon. In some embodiments, the silicon is doped, for example, with donor (e.g., phosphorus, arsenic, antimony, etc.) or acceptor (e.g., boron, aluminum, gallium, etc.) atoms, and the silicon is N- or P-type silicon. In some such embodiments, the silicon is heavily doped and is highly conductive. The nanoribbon, e.g., including silicon, may continue into a structure having sidewalls. The nanoribbon may be one in a vertical stack spanning laterally between sidewalls. In some embodiments, vertically adjacent nanoribbons are connected internal to the structures, e.g., in connected pairs. In some embodiments, 10 or 20 nanoribbons (or more) span between the sidewalls.

The nanoribbon may be a few nanometers thick, or thicker or thinner. Other dimensions, for example, a length and width (e.g., in the x and y directions, respectively), of the nanoribbon may vary, e.g., to suit an application. For example, nanoribbons with smaller dimensions may be desirable, e.g., to improve device density, but some dimensions may be kept above certain thresholds to ensure satisfactory operation, e.g., at high frequencies and of sufficient conduction. A greater or lesser nanoribbon width may correspond to a channel region's greater or lesser conducting cross-sectional area and a greater or lesser aggregate channel width for a transistor. A nanoribbon with a greater width may be a nanosheet, and a nanoribbon grown with a lesser width may be a nanowire. A longer nanoribbon length may be desired, depending on nanoribbon width, e.g., to avoid short-channel effects.

FIG. 2A shows a stack of nanoribbons 220 spanning between and coupling two terminals 211, 212 over a substrate 201 in an IC die 200, for example, as may be received at operation 110 of processes or methods 100. Sidewall spacers 213, 214 are on terminals 211, 212, and sidewall spacers 215, 216 are on spacers 213, 214. Nanoribbons 220 are part of a scaffold assembly 219, some of which is exposed between terminals 211, 212. Obscured portions of scaffold assembly 219, for example, behind a front surface of terminals 211, 212, and spacers 213, 214, 215, 216, are shown with dashed lines. In some embodiments, at least some of the surfaces of the received structure(s) are covered, for example, by sidewall spacers 213, 214 continuing around terminals 211, 212.

The stack of nanoribbons 220 may include pairs of nanoribbons connected internal to terminals 211, 212, as shown, but any nanoribbon 220 need not be connected to another nanoribbon 220. The stack may include a larger quantity of nanoribbons 220, e.g., 10, 20, or more. The stack may include an odd number of nanoribbons 220, e.g., one, three, 19, etc. ISE with an odd number of nanoribbons 220, all but one nanoribbon 220 are connected to a vertically adjacent nanoribbon 220, e.g., where one nanoribbon 220 has been removed. In other embodiments with an odd number of nanoribbons 220, no nanoribbons 220 are connected to any other nanoribbon 220. The operations described below may be performed on one, some, or all of the received nanoribbons 220.

In the example of FIG. 2A, nanoribbons 220 and scaffold assembly 219 are predominantly silicon. In some embodiments, at least portions of nanoribbons 220 or and scaffold assembly 219 include one or more other materials.

Sidewall spacers 213, 214, 215, 216 may be insulators, e.g., low-K dielectric materials. In some embodiments, at least some of spacers 213, 214, 215, 216 are sacrificial layers. In the example of FIG. 2A, IC die 200 is received, e.g., at operation 110, with spacers 213, 214, 215, 216 on terminals 211, 212. In some embodiments, spacers 213, 214, 215, 216 are deposited on terminals 211, 212 after receipt.

Returning to FIG. 1 and processes or methods 100, at least a center portion of the nanoribbon is oxidized at operation 120. The oxidizing may beneficially alter the chemical or electrical characteristics of that portion of the nanoribbon. For example, the nanoribbon may be predominantly silicon, e.g., heavily doped silicon, and oxidizing the nanoribbon center may convert that portion of the nanoribbon from conductive to insulating. In some embodiments, oxidizing a portion of the nanoribbon effects an etch selectivity between the oxidized portion and another material. In some such embodiments, the etch selectivity is between the oxidized and unoxidized portions. The nanoribbon may be oxidized by any suitable means, for example, thermal oxidation of silicon by either dry (e.g., O₂) or wet (e.g., H₂O) oxidation.

In some embodiments, masking structures cover portions of the nanoribbon during oxidation operation 120. In some such embodiments, an exposed portion of the nanoribbon is oxidized and the covered portions remain unoxidized. For example, sacrificial sidewalls over terminal sidewalls (or over insulating sidewalls over terminal sidewalls) may also cover end portions of the nanoribbon during an oxidation operation 120. The sacrificial sidewalls may then be removed, e.g., by a selective and isotropic etch, leaving an oxidized center of the nanoribbon between unoxidized, end portions of the exposed nanoribbon (adjacent remaining sidewalls). In some embodiments, a scaffolding of predominantly silicon includes a nanoribbon with an exposed silicon dioxide center between exposed silicon ends.

FIG. 2B illustrates a stack of nanoribbons 220 between terminals 211, 212 in IC die 200, for example, after operation 120 of processes or methods 100. The exposed portions of nanoribbons 220 (e.g., between inner sidewall spacers 215, 216) are of a silicon oxide (e.g., silicon dioxide, SiO₂). Other portions of nanoribbons 220 and scaffold assembly 219 (e.g., within and covered by terminals 211, 212 and spacers 213, 214, 215, 216) are predominantly silicon.

FIG. 2C shows nanoribbons 220 between terminals 211, 212, for example, in IC die 200 of FIG. 2B without spacers 215, and with exposed end portions 221, 222 of nanoribbons 220. The portion of IC die 200 adjacent scaffold assembly 219 (including portions of terminals 211, 212) is magnified to show greater detail. Exposed end portions 221, 222 of nanoribbons 220 are of silicon (as is scaffold assembly 219, covered by terminals 211, 212 and spacers 213, 214). Center portions 223 of nanoribbons 220 are of a silicon oxide (in the example of FIG. 2C, silicon dioxide, SiO₂).

Returning to FIG. 1, a channel layer is formed coupled to the end portions of the nanoribbon at operation 130 of processes or methods 100. The channel layer may be formed by any suitable means. In some embodiments, the channel layer is formed by depositing a channel material on a structure adjacent the end portions of the nanoribbon. For example, one or more channel layers may be formed above and/or below nanoribbon end portions by depositing a channel material over both an oxidized, center portion of a nanoribbon and unoxidized nanoribbon end portions. The channel material may be deposited by chemical vapor deposition (CVD), which may allow for conformally depositing the channel material on unoxidized end portions of the nanoribbon. In some such embodiments, a channel material may be deposited by metalorganic CVD (MOCVD), which may facilitate epitaxially forming crystalline thin films of the channel material. A channel layer may also be epitaxially formed by molecular-beam epitaxy (MBE). Epitaxial deposition may beneficially result in a crystalline channel layer, e.g., a monocrystalline channel region, with superior conductivity relative to an amorphous channel layer.

Advantageously, the channel material may be semiconducting while having a high conductivity, even in a very thin layer. For example, the channel material may be a 2D material. Some 2D materials are highly conductive, semiconducting, and may be deposited as described (e.g., by CVD or MBE) in crystalline monolayers (e.g., in layers having a thickness of a single molecule). In some embodiments, the channel material includes a TMD. TMD are compounds containing a transition metal and a chalcogen. The transition metal may be an element in any of groups 4 through 11, the group 3 elements scandium and yttrium, and the inner transition metals (e.g., f-block lanthanide and actinide series). The chalcogens are the group 16 elements, but excluding oxygen. Notable chalcogens are sulfur, selenium, and tellurium. TMD may be deposited using, for example, CVD (both MOCVD and other deposition methods) or MBE. In some embodiments, multiple layers of a 2D material are deposited. Advantageously, a channel layer includes a monocrystalline monolayer of a semiconducting material. Channel regions with other materials and structures may be formed.

FIG. 2D illustrates IC die 200 with channel regions 225 of nanoribbons 220 coupled to end portions 221, 222 of nanoribbons 220, for example, after operation 130 of processes or methods 100. The magnified portion of IC die 200, including scaffold assembly 219, is shown. In some embodiments, nanoribbon 220 includes multiple layers of a 2D material. In the example of FIG. 2D, nanoribbons 220 include TMD monolayer channel regions 225 above and below oxidized center portions 223. Each channel region 225 is between corresponding end portions 221, 222, one above and one below corresponding end portions 221, 222. The conduction of TMD monolayer channel regions 225 may be controlled to electrically connect (or not) the highly conductive (e.g., heavily doped) silicon end portions 221, 222 of nanoribbons 220 by bypassing the electrically insulating center portions 223 of oxidized silicon.

Returning to FIG. 1 and processes or methods 100, an insulator material is deposited over the channel layer at operation 140. The insulator material may be a gate dielectric deposited over one (or more) nanoribbon or the stack of nanoribbons. The insulator material may electrically insulate a nanoribbon from an electrically conductive material, e.g. a gate electrode, to be formed adjacent to the stack of nanoribbons. The insulator material may be one of multiple insulator materials over the stack of nanoribbons. The insulator material may be a high-k dielectric material, which may advantageously allow for a thicker layer of insulator material and lower gate leakage currents. The insulator material may be deposited by any suitable means. In some embodiments, the insulator material is deposited conformally, e.g., above, below, and on the sides of a nanoribbon. In some embodiments, the insulator material is deposited by CVD.

FIG. 2E shows IC die 200 with gate insulator 235 over channel regions 225, for example, after operation 140 of processes or methods 100. Gate insulator 235 is above channel regions 225, below channel regions 225, and may be on the sides (e.g., conformally, in front and behind) channel regions 225. The one or more layers of gate insulator 235 may include a silicon oxide (e.g., silicon dioxide, SiO₂) and/or a high-k dielectric material. Examples of high-k materials that may be used in gate insulator 235 include, but are not limited to, hafnium oxide, lanthanum oxide, zirconium oxide, tantalum oxide, titanium oxide, and aluminum oxide. Gate insulator 235 may include other materials.

Returning to FIG. 1, a gate terminal is deposited over the insulator material at operation 150 of processes or methods 100. The gate terminal may include one or metals or other conductive material(s) and may depend on whether the transistor is a P-type or N-type transistor. The gate terminal may be formed by any suitable means, e.g., by CVD, conformally over the insulator material. In some embodiments, after a first gate metal is deposited, a second gate metal is then filled in over the first gate metal. The gate terminal may be deposited above, below, and all around the insulator material and a nanoribbon. Gate terminals over one or more nanoribbons may be integrated with gate terminals for other nanoribbons into a gate terminal for a stack of nanoribbons.

FIG. 2F illustrates transistor structure 202 in IC die 200, including gate terminal 245 over gate insulator 235, for example, after operation 150 of processes or methods 100. Gate terminal 245 is on gate insulator 235 and may include at least one of a P- or an N-type work function metal, depending on whether the transistor is a P- or N-type transistor. In some embodiments, gate terminal 245 includes two or more metal layers, where one or more metal layers are work function metal layers and at least one metal layer is a fill metal layer. For a P-type transistor, metals that may be used for the gate electrode include, but are not limited to, ruthenium, palladium, platinum, cobalt, nickel, and conductive metal oxides, e.g., ruthenium oxide. For an N-type transistor, metals that may be used for the gate electrode include, but are not limited to, hafnium, zirconium, titanium, tantalum, aluminum, alloys of these metals, and carbides of these metals, such as hafnium carbide, zirconium carbide, titanium carbide, or tantalum carbide.

FIG. 2G shows IC die 200 with transistor structure 202 having channel regions 225 in a stack of nanoribbons 220 spanning between source and drain terminals 211, 212 over substrate 201. Multiple channel regions 225 are in the same or similar transistor structure 202 as described in, for example, FIG. 2F. Nanoribbons 220 span a distance 210 between terminals 211, 212. Each nanoribbon 220 includes end portions 221, 222 and two layers of channel region 225. Each channel region 225 couples corresponding end portions 221, 222. Each channel region 225 is between corresponding end portions 221, 222, one above and one below corresponding end portions 221, 222. In the example of FIG. 2G, each channel region 225 is a crystalline TMD monolayer and includes a transition metal and a chalcogen. For each nanoribbon 220, end portions 221, 222 are predominantly silicon in a plane between planes of corresponding channel regions 225 above and below (in the same nanoribbon 220). Also planar with the silicon end portions 221, 222, center portion 223 of each nanoribbon 220 is between planes of channel region 225 layers. Center portions 223 include oxygen (e.g., in a silicon oxide). Gate electrode material 245 is over nanoribbons 220 and gate insulator 235 and spans a portion of distance 210 between terminals 211, 212. For each nanoribbon 220, gate insulator 235 is between channel regions 225 and gate electrode material 245. Gate electrode material 245 is shared between some channel regions 225 (e.g., those between a same pair of oxidized center portions 223 of nanoribbons 220). The stack of nanoribbons 220 may have gate electrode material 245 in a common, integrated gate structure that couples layers of gate electrode material 245 in front and behind the stack.

IC die 200 is coupled to a host component 299. IC die 200 is coupled to a power supply (not shown) through host component 299. Host component 299 may be any substrate with interconnect interfaces (not shown), such as a package substrate or interposer, another IC die, a printed circuit board, etc. Host component 299 may itself be coupled to a host component, such as a printed circuit board, a package substrate or interposer, another IC die, etc.

In some embodiments, channel region 225 includes tungsten and either sulfur or selenium (e.g., WS₂ or WSe₂). In some embodiments, channel region 225 includes molybdenum and either sulfur or selenium (e.g., MoS₂ or MoSe₂). Tungsten and molybdenum are both well-characterized metals advantageously compatible with IC processing flows. These compounds (WS₂, WSe₂, MoS₂, and MoSe₂) are stable, semiconducting 2D materials.

Sidewall spacers 213, 214 are electrical insulators between, for example, channel regions 225 and source and drain terminals 211, 212, and between gate electrode material 245 and source and drain terminals 211, 212. For example, spacers 213, 214 may be of low-k dielectric materials, e.g., to minimize crosstalk between terminals. In some embodiments, IC die 200 is received with spacers 213, 214 on sidewalls of terminals 211, 212. In some embodiments, spacers 213, 214 are deposited, or otherwise formed, on sidewalls of source and drain terminals 211, 212, e.g., after sacrificial spacers 213, 214 are removed during manufacture. Sacrificial spacers 213, 214 (and their removal) may facilitate processing, e.g., of channel regions 225 or end portions 221, 222 of nanoribbons 220 exposed by the removal of sacrificial spacers 213, 214.

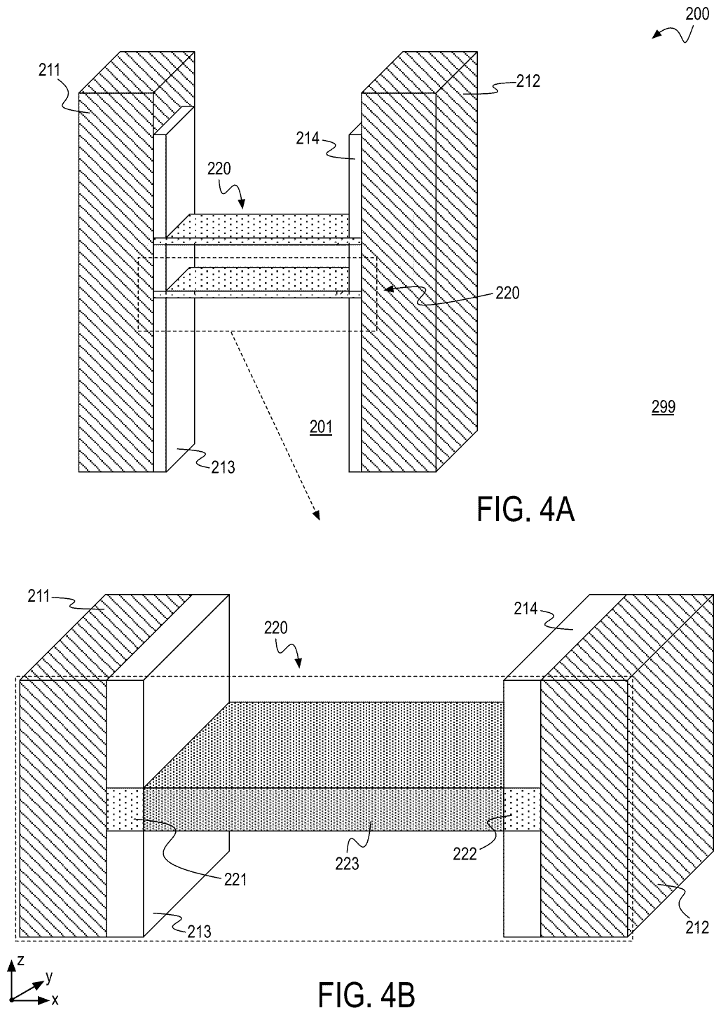

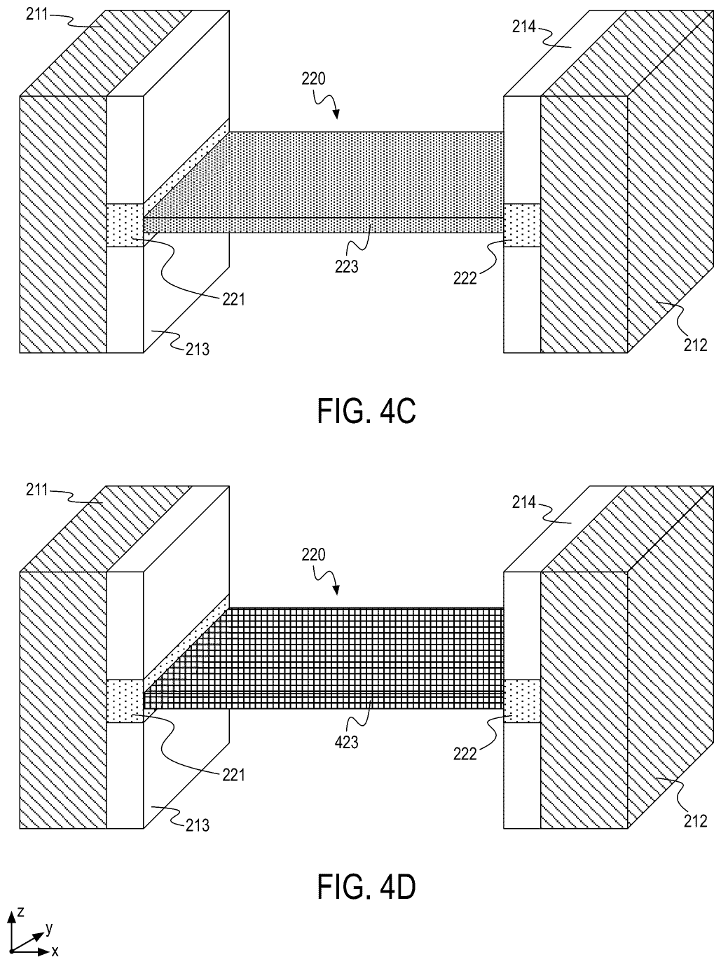

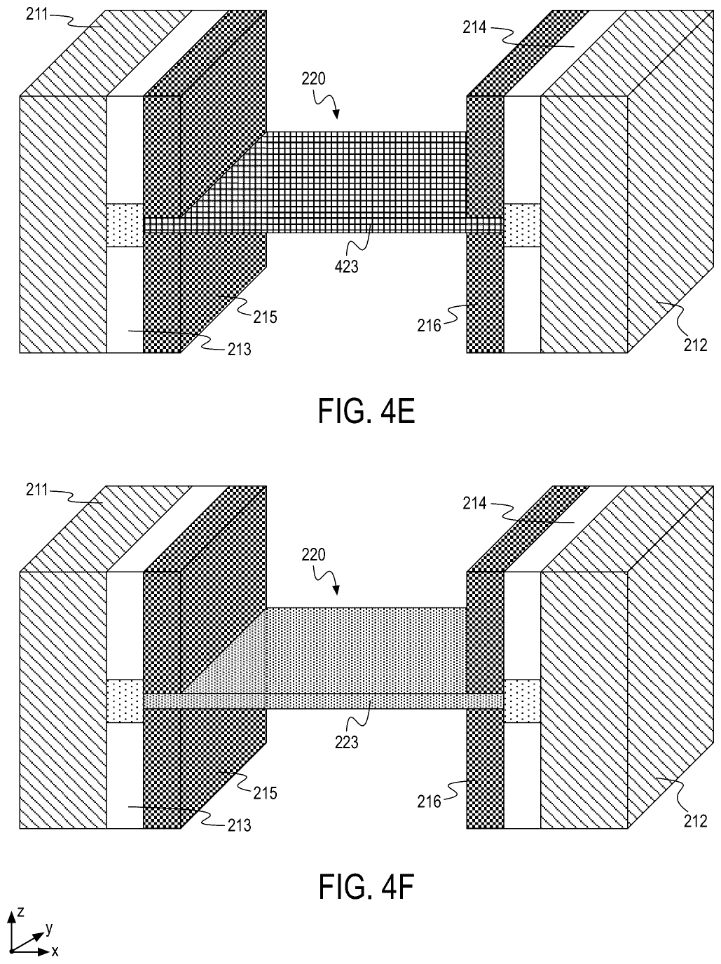

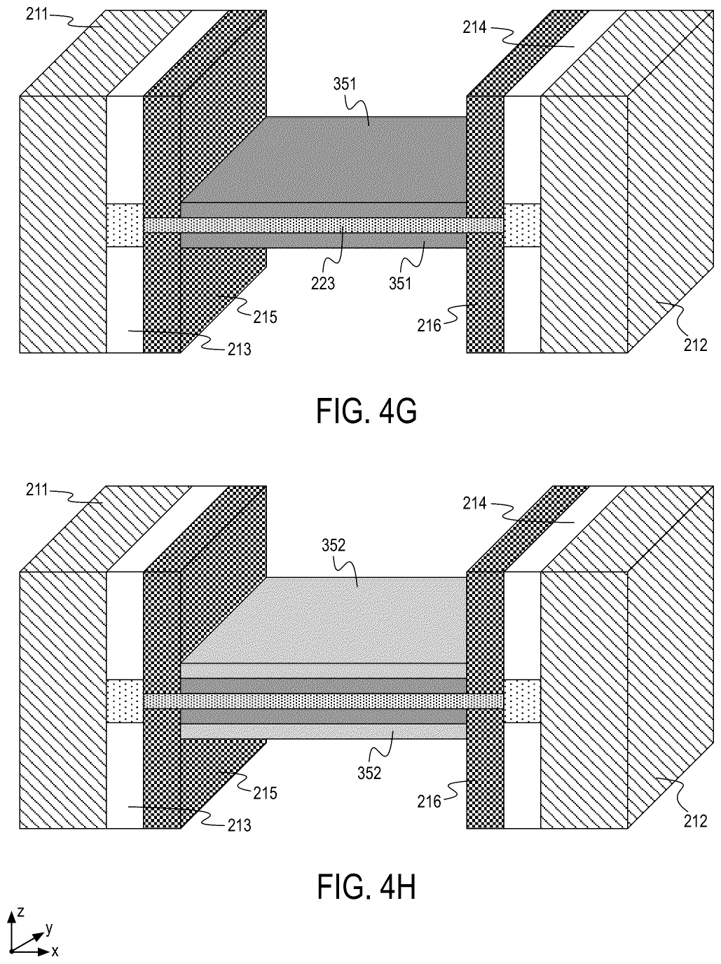

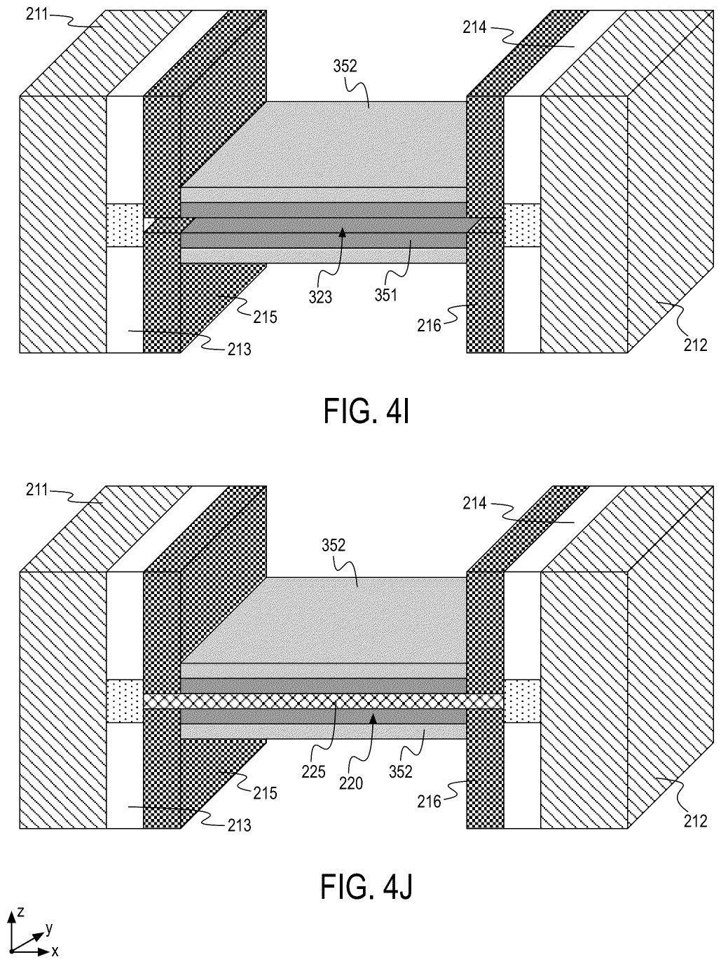

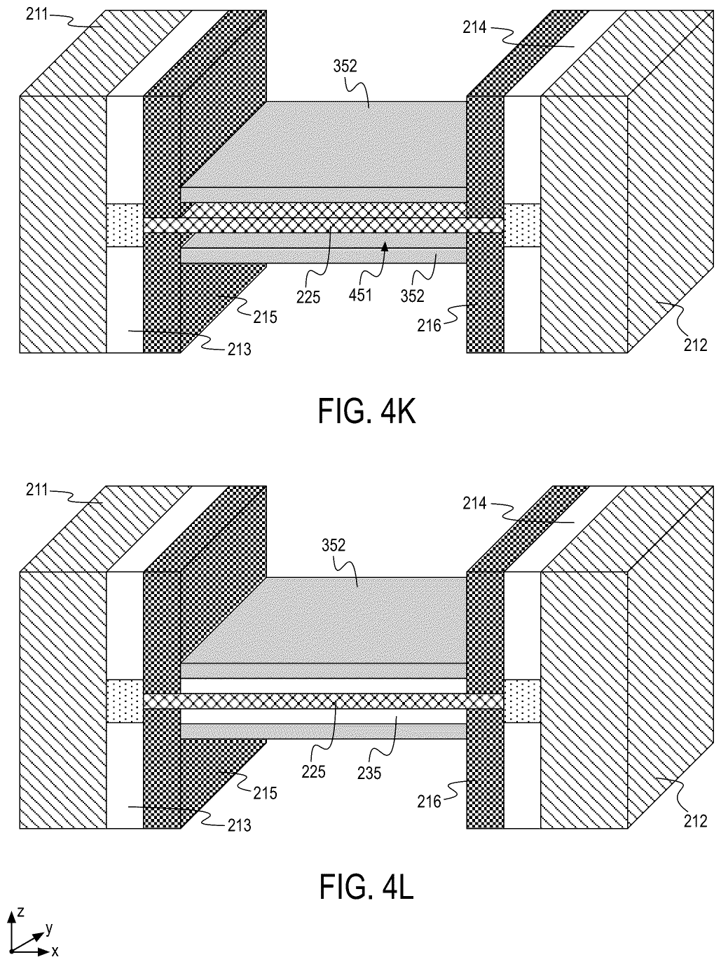

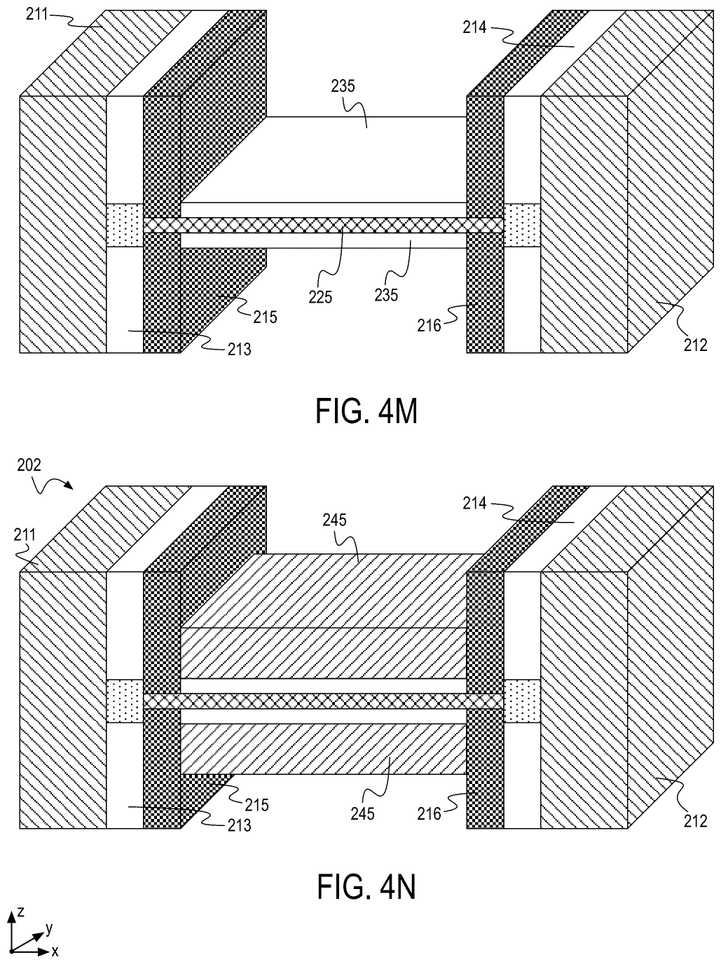

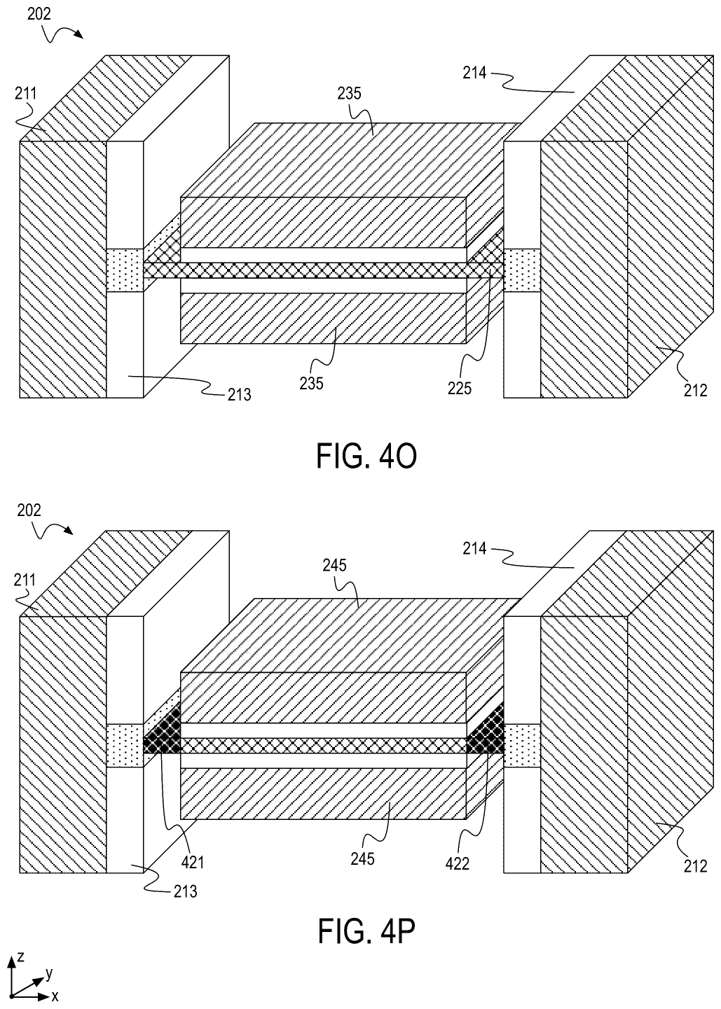

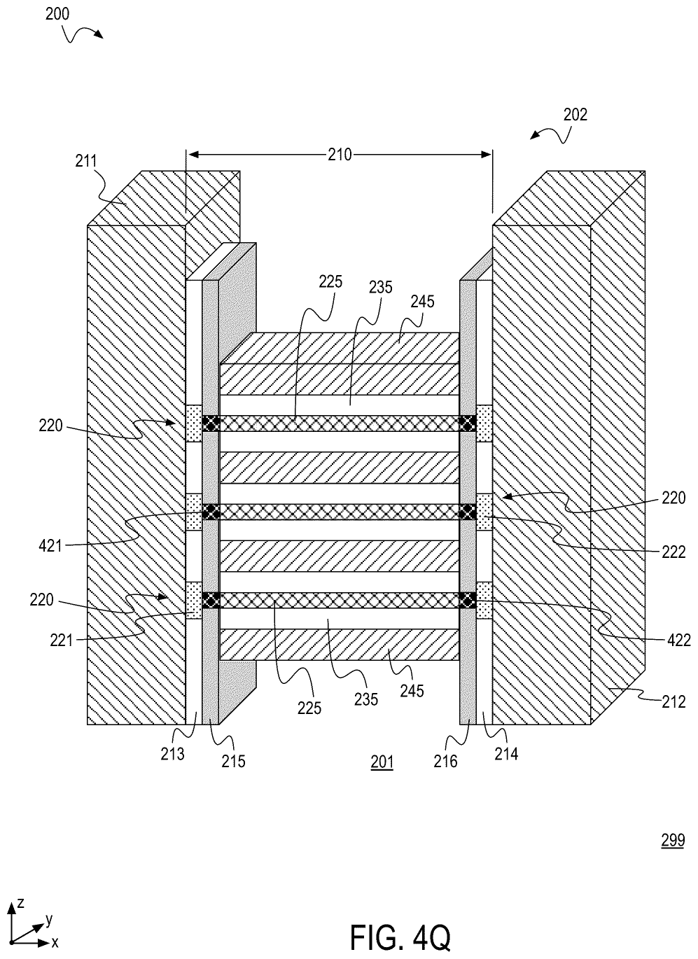

Returning to FIG. 1 and processes or methods 100, an end region of a channel layer or nanoribbon is optionally modified at operation 160. Such modification may improve the electrical and/or mechanical coupling between a channel layer and a terminal, for example, a nanoribbon end portion. Modifying a channel layer or nanoribbon end region will be described further below, for example, in FIG. 4P.

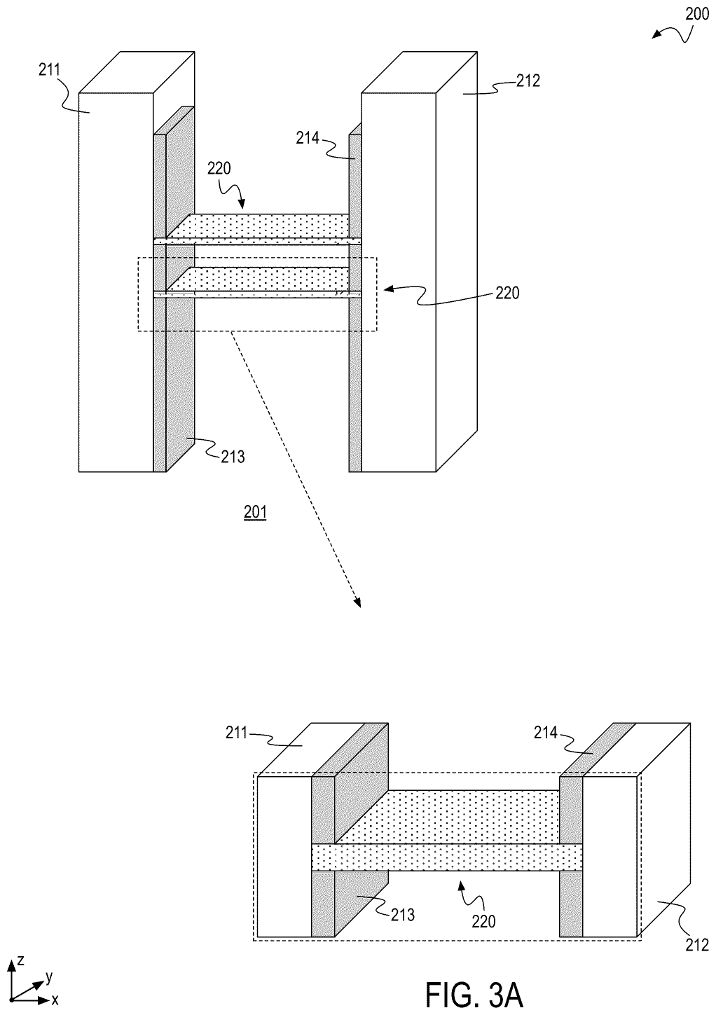

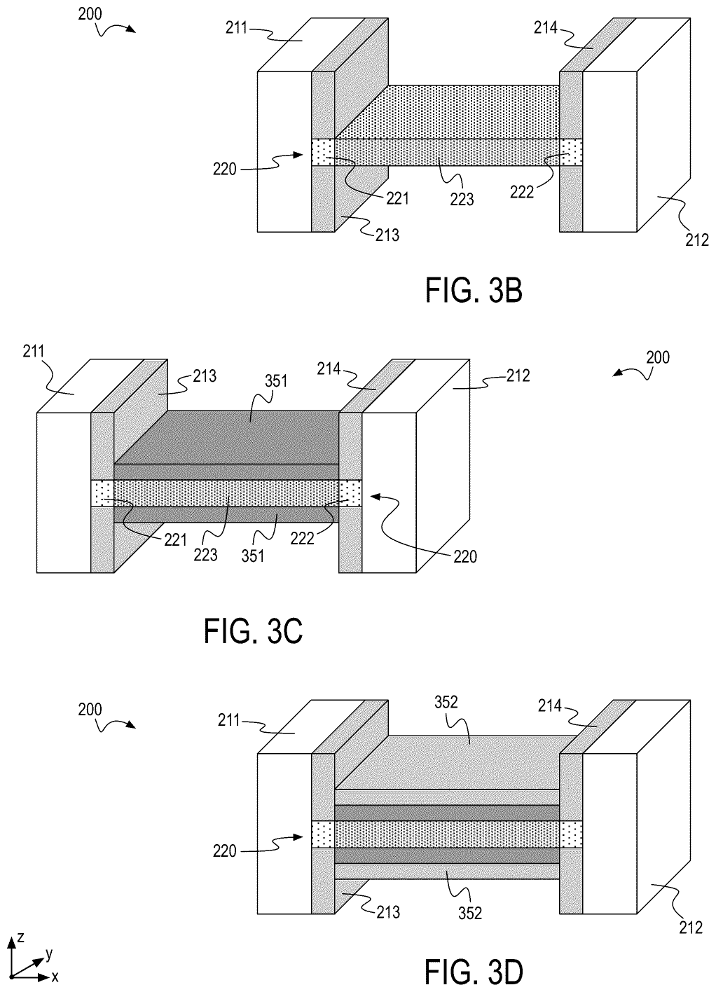

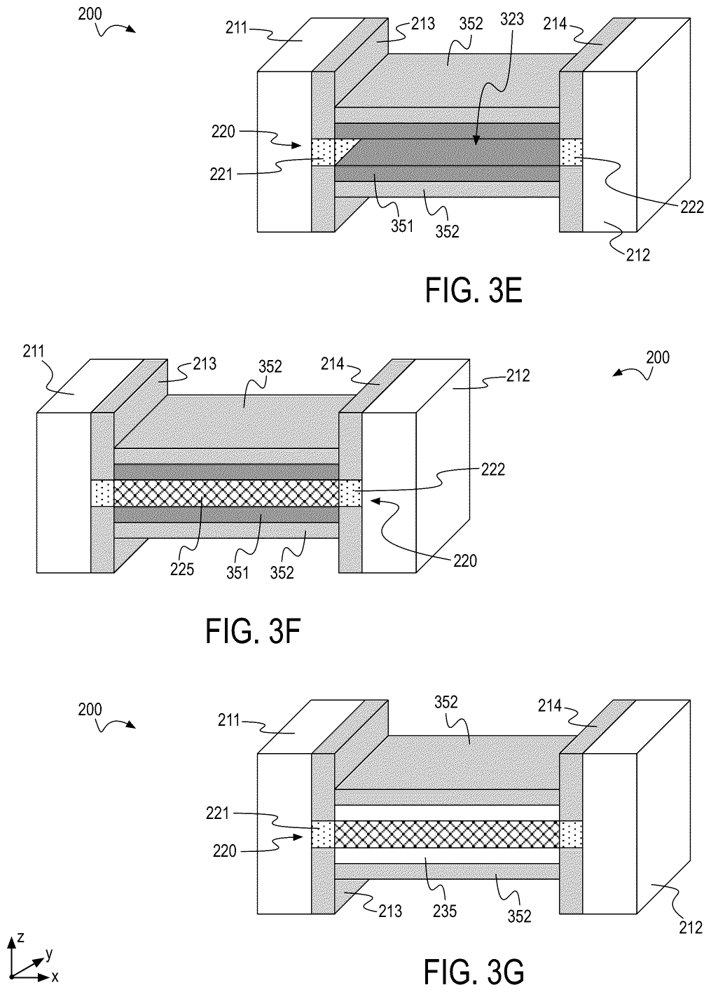

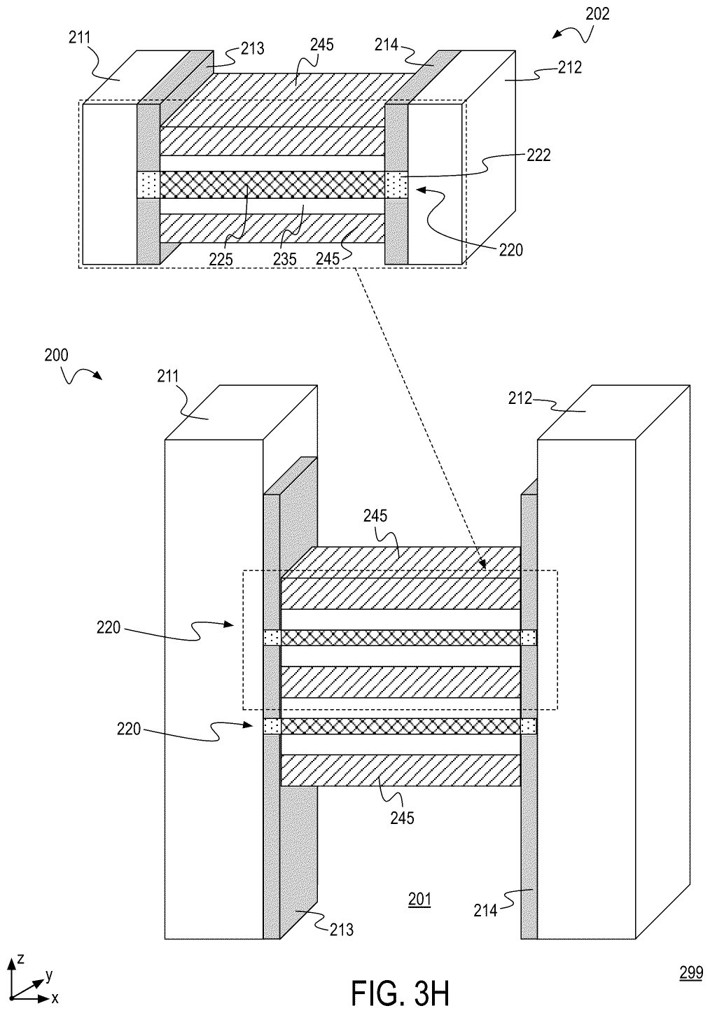

FIGS. 3A, 3B, 3C, 3D, 3E, 3F, 3G, and 3H illustrate isometric views of a transistor structure 202 with a stack of nanoribbons 220 spanning between source and drain terminals 211, 212, at various stages of manufacture, in accordance with some embodiments. FIGS. 3A-3H show an example progression of structures as operations of processes or methods 100 are performed. The example structures have some similarities with, e.g., the progression shown in FIGS. 2A-2G. As will be described below, at least one difference between the examples illustrates a different means of forming a channel layer coupled to end portions of a nanoribbon at operation 130 of processes or methods 100.

FIG. 3A shows a stack of nanoribbons 220 spanning between and coupling terminals 211, 212 over substrate 201 in IC die 200, e.g., similar to as was described in FIG. 2A and received at operation 110 of processes or methods 100. For example, the stack of nanoribbons 220 may include more nanoribbons 220, e.g., 10 or more nanoribbons 220. Sidewall spacers 213, 214 are on terminals 211, 212 and may be electrical insulators, e.g., of a low-k dielectric material. Nanoribbons 220 may be part of a scaffold assembly, portions of which may be obscured, for example, behind a front surface of terminals 211, 212. Having shown the context of IC die 200, e.g., a stack of multiple 2D nanoribbons 220 coupling terminals 211, 212, a single nanoribbon 220 is magnified to show greater detail.

FIG. 3B illustrates a magnified portion of IC die 200, for example, after an oxidizing operation (such as operation 120 of processes or methods 100) is performed on the structures described in FIG. 3A. Center portion 223 of nanoribbon 220 (e.g., between sidewall spacers 213, 214) are of a silicon oxide (e.g., silicon dioxide, SiO₂). End portions 221, 222 of nanoribbons 220 (and any obscured scaffold assembly within or covered by terminals 211, 212) are predominantly silicon. In some embodiments, nanoribbon 220 includes a material other than silicon, and center portion 223 includes an oxide other than a silicon oxide.

The oxidation of center portion 223 may provide an etch selectivity between center portion 223 and end portions 221, 222 of nanoribbons 220. Such an etch selectivity may be exploited as part of forming a channel layer coupled to end portions 221, 222 of nanoribbons 220, e.g., at operation 130 of processes or methods 100. The oxidation and consequent etch selectivity may facilitate the removal of center portion 223 while end portions 221, 222 are retained. In some embodiments, a channel layer is formed coupled to end portions 221, 222 by forming a support layer over oxidized center portion 223, creating a void adjacent the support layer by removing oxidized center portion 223, and forming the channel layer over the support layer. The void may be between end portions 221, 222 and support layer(s) (which may act as a substrate, template, or scaffold for the formation of the channel layer) such that the channel layer formed may be coupled to end portions 221, 222. The support layer may be a sacrificial layer. In some embodiments, a support layer is conformally deposited over oxidized center portion 223. Formation of a support layer, e.g., as part of operation 130, may be by any suitable means, for example, a CVD or atomic layer deposition (ALD).

FIG. 3C shows a magnified portion of IC die 200, for example, after a support layer 351 has been formed over oxidized center portion 223, e.g., as part of operation 130 of processes or methods 100. Support layer 351 may be a sacrificial layer. There may be an etch selectivity between support layer 351 and oxidized center portion 223 and between an eventual channel layer and support layers 351, e.g., to support eventual removal of oxidized center portion 223 (and retention of support layer 351) or sacrificial support layer 351 (and retention of an eventual channel layer).

Support layer 351 may be a preferential-growth layer of any suitable material that may, for example, preferentially support growth (such as deposition) of a channel material, e.g., a 2D material. Support layer 351 may advantageously be a crystalline substrate to facilitate crystalline, e.g., epitaxial, growth of a channel layer, for example, between support layers 351. In some embodiments, support layer 351 includes crystalline sapphire (e.g., Al₂O₃). Other materials that may preferentially support growth of a channel material include molybdenum, tungsten, molybdenum oxide, and tungsten oxide. Some such materials may act as a source for a channel material, for example, a 2D material, such as a TMD monolayer. In some embodiments, support layer 351 includes a zirconium oxide (e.g., ZrO₂), which may be retained as a high-k dielectric. In some embodiments, for example, without silicon end portions 221, 222 and silicon oxide center portion 223, support layer 351 includes a silicon oxide (e.g., SiO₂).

FIG. 3D illustrates IC die 200 with a non-growth layer 352 over support layer 351. Non-growth layer 352 may be a sacrificial layer. Non-growth layer 352 may have an etch selectivity with support layer 351. In some such embodiments, non-growth layer 352 confines the deposition of a gate dielectric over a channel material after a sacrificial support layer 351 is removed. Non-growth layer 352 may include a non-preferential growth material such that a channel material may not deposit (or otherwise grow) on non-growth layer 352. Non-growth layer 352 may include a silicon nitride (such as Si₃N₄) or amorphous Al₂O₃.

FIG. 3E shows IC die 200 with a void 323 adjacent and between support layers 351. Oxidized center portion 223 is absent between support layers 351 and between end portions 221, 222. In some embodiments, void 323 is opened adjacent support layer 351 (e.g., as part of operation 130 of processes or methods 100) by removing oxidized center portion 223 with an isotropic etch selective to oxidized center portion 223 (e.g., silicon oxide).

FIG. 3F illustrates IC die 200 with channel region 225 over and between support layers 351. Channel region 225 may be formed at operation 130 of processes or methods 100. Nanoribbon 220 includes channel region 225, which is between and coupled to end portions 221, 222. In some embodiments, channel region 225 is of a 2D material. In some such embodiments, channel region 225 is of a TMD material and has a thickness of a monolayer. A thickness of channel region 225 may be less than 1 nm. Channel region 225 may be of a TMD material but with a thickness of two molecular layers, e.g., less than 2 nm. In some embodiments, channel region 225 is deposited as previously described.

FIG. 3G shows IC die 200 with gate insulator 235 over channel region 225 and between non-growth layers 352, for example, after a deposition operation (such as operation 140 of processes or methods 100). In some embodiments, gate insulator 235 is of a high-k dielectric material as previously described. In some embodiments, gate insulator 235 are deposited (e.g., as previously described) over channel region 225 and between channel region 225 and non-growth layers 352, for example, after support layers 351 are removed. In some such embodiments, support layers 351 are removed by an isotropic etch selective to sacrificial support layers 351. In some embodiments, support layers 351 are retained as gate insulator 235.

FIG. 3H illustrates IC die 200 with transistor structure 202 having gate electrode material 245 over gate insulator 235 and without non-growth layers 352, for example, after a deposition operation (such as operation 150 of processes or methods 100). Non-growth layers 352 may be removed by an isotropic etch selective to sacrificial non-growth layers 352. Transistor structure 202 includes channel regions 225 in a stack of multiple 2D nanoribbons 220 spanning the distance between source and drain terminals 211, 212 over substrate 201. Each nanoribbon 220 includes channel region 225 between, coplanar with, and coupled to end portions 221, 222. Sidewall spacers 213, 214 electrically insulate channel regions 225 from source and drain terminals 211, 212, and gate electrode material 245 from source and drain terminals 211, 212. IC die 200 is coupled to a host component 299.

FIGS. 4A, 4B, 4C, 4D, 4E, 4F, 4G, 4H, 4I, 4J, 4K, 4L, 4M, 4N, 4O, 4P, and 4Q illustrate isometric views of transistor structure 202 spanning between source and drain terminals 211, 212, in accordance with some embodiments. FIGS. 4A-4Q show an example progression of structures as operations of processes or methods 100 are performed. The example structures have some similarities with previous progressions shown, but the following sequence additionally illustrates optional means for treating nanoribbon contact regions at operation 160 of processes or methods 100, as well as optionally thinning an oxidized portion of a nanoribbon, both as will be described below.

FIG. 4A shows IC die 200 with nanoribbons 220 spanning between and coupling terminals 211, 212 over substrate 201, such as may be received at operation 110 of processes or methods 100. The stack of nanoribbons 220 may include more nanoribbons 220. Nanoribbons 220 may be of silicon or any suitable material.

FIG. 4B illustrates a magnified portion of IC die 200 with an oxidized center portion 223 between end portions 221, 222 (covered by sidewall spacers 213, 214), for example, after performing an oxidizing operation (such as operation 120 of processes or methods 100, as previously described). End portions 221, 222 may include silicon, and center portion 223 may include a silicon oxide.

Processes or methods 100 may optionally include removing an upper or lower section of oxidized center portion 223. FIG. 4C shows a thinner oxidized center portion 223 between end portions 221, 222, which have retained their previous thicknesses. End portions 221, 222 have exposed surfaces above and below thinner oxidized center portion 223. In some embodiments, upper or lower sections of oxidized center portion 223 are removed, e.g., by a selective and isotropic etch. A thinner oxidized center portion 223 may allow for subsequent support layers and a void therebetween to confine deposition of a 2D channel material, e.g., to a single monolayer. In some embodiments, oxidized center portion 223 is thinned to approximately 0.7 nm. In some embodiments, oxidized center portion 223 is thinned to approximately 1.4 nm, which may allow for the flow of precursor gases for a 2D material, but confine 2D nanoribbon formation to two or fewer molecular layers.

FIG. 4D illustrates nanoribbon 220 with a self-assembled monolayer (SAM) 423, e.g., of organic molecules, on oxidized center portion 223. SAM 423 may, as a monolayer, be very thin, which may be advantageous over other masking materials. SAM 423 may be formed by any suitable means. In some embodiments, SAM 423 are selectively deposited on oxidized center portion 223 (e.g., selectively to an oxide of silicon, such as SiO₂). SAM 423 may passivate oxidized center portion 223, e.g., during subsequent processing.

FIG. 4E shows sidewall spacers 215, 216 over sidewall spacers 213, 214. Spacers 215, 216 may mask covered portions of nanoribbon 220 from some subsequent processing. Spacers 215, 216 may be deposited, e.g., conformally, by any suitable means. Passivation SAM 423 over oxidized center portion 223 may inhibit bonding of spacers 215, 216 with oxidized center portion 223, which may be beneficial, e.g., when removing oxidized center portion 223.

FIG. 4F illustrates sidewall spacers 215, 216 over sidewall spacers 213, 214 and without SAM 423 over oxidized center portion 223 of nanoribbon 220. SAM 423 may be removed by any suitable means, e.g., with an etchant selective to SAM 423.

FIG. 4G shows nanoribbon 220 (which includes end portions 221, 222 and center portion 223), for example, after support layer(s) 351 has been formed over exposed oxidized center portion 223, e.g., as part of forming a channel layer at operation 130 of processes or methods 100. Spacers 215, 216 cover outer portions of oxidized center portion 223 adjacent end portions 221, 222 of nanoribbon 220. Support layer(s) 351 may be of a sacrificial material.

FIG. 4H illustrates non-growth layer(s) 352 over support layer(s) 351. Non-growth layer 352 may be a sacrificial layer with an etch selectivity with support layer 351. Non-growth layer 352 may be formed as previously described.

FIG. 4I shows void 323 adjacent support layer(s) 351. Oxidized center portion 223 is absent between support layers 351 and between end portions 221, 222. Void 323 may be created adjacent support layer 351 (e.g., as part of forming a channel layer at operation 130 of processes or methods 100) as previously described, for example, selective etching. Void 323 may have the narrow vertical dimension matching that of thinned oxidized center portion 223, e.g., 0.7 nm. The removal of oxidized center portion 223 (e.g., from between support layer(s) 351, spacers 215, 216, and end portions 221, 222) may benefit from the passivation of center portion 223 by SAM 423 before the forming of spacers 215, 216.

FIG. 4J illustrates with channel region 225 of nanoribbon 220 over and between support layer(s) 351. Channel region 225 may be a layer formed at operation 130 of processes or methods 100. Nanoribbon 220 includes channel region 225 between and coupled to end portions 221, 222. Channel region 225 may be deposited, as previously described, over support layer(s) 351, which may preferentially support growth of a layer of channel material, e.g., a monolayer of TMD or other 2D material. Support layer(s) 351 may template growth laterally in narrow void 323.

FIG. 4K shows channel region 225 of nanoribbon 220 with support layer(s) 351 absent and void(s) 451 between channel region 225 and non-growth layer(s) 352. Support layer(s) 351 may be removed as previously described, e.g., by an isotropic etch selective to support layer(s) 351 that retains channel region 225 and non-growth layer(s) 352.

FIG. 4L illustrates nanoribbon 220 (including end portions 221, 222 and channel region 225) with gate insulator 235 over a portion of channel region 225 and between non-growth layers 352, for example, after a deposition operation (such as operation 140 of processes or methods 100). Gate insulator 235 may be a high-k dielectric material. In some embodiments, gate insulator 235 is a retained (non-sacrificial) support layer 351. In some embodiments, gate insulator 235 is deposited as previously described.

FIG. 4M shows gate insulator 235 over a portion of channel region 225 without non-growth layer(s) 352, which may be removed by any suitable means, e.g., a selective isotropic etch.

FIG. 4N illustrates transistor structure 202 with gate electrode material 245 over gate insulator 235 and channel region 225, for example, after a deposition operation (such as operation 150 of processes or methods 100). Gate electrode material 245 may be formed as previously described, including in multiple operations (e.g., a first gate metal deposition and second gate metal fill). A gate voltage on gate electrode material 245 may control conduction between source and drain terminals 211, 212 through channel region 225 (and end portions 221, 222) of nanoribbon 220.

FIG. 4O shows transistor structure 202 with a gate structure (including gate electrode material 245 and gate insulator 235) over channel region 225 with sidewall spacers 215, 216 absent. Nanoribbon end portions 221, 222 (e.g., of silicon, between upper and lower portions of sidewall spacers 213, 214) and contact regions of channel region 225 (between nanoribbon end portions 221, 222 and gate insulator 235) are exposed with sidewall spacers 215, 216 absent. Spacers 215, 216 may be removed by an isotropic etch selective to spacers 215, 216, which retains nanoribbon 220, gate electrode material 245, gate insulator 235, and sidewall spacers 213, 214.

FIG. 4P illustrates transistor structure 202 with contact regions 421, 422 of nanoribbon 220, for example, after a modification operation (such as operation 160 of processes or methods 100). Contact regions 421, 422 of nanoribbon 220 are between nanoribbon end portions 221, 222 (e.g., of silicon) and channel region 225. Channel region 225 is between contact regions 421, 422. Contact regions 421, 422 may include the same channel material as channel region 225. Contact regions 421, 422 may be modified, for example, to reduce a series resistance, e.g., a contact resistance between end portions 221, 222 and channel region 225 of nanoribbon 220.

For example, contact regions 421, 422 of nanoribbon 220 may be end regions of channel region 225 modified by adding a dopant to the layer of channel material. Doping of the channel material may adjust the materials fermi level up or down to fully dope the P- or N-type channel material. In some embodiments, contact regions 421, 422 are heavily doped. Some examples of dopants are Re, N, Ta, Hf, Ru, Nb, Zr, Y, Tc, Rh, Co, Fe, Mn, Sc, Ti, V, Cu, Ni, Sb, I, As, Br, P, Cl, and F. In some embodiments, nanoribbon 220 includes a monolayer of TMD between and coupling silicon end portions 221, 222, and the monolayer of TMD includes channel region 225 (without a dopant) between contact regions 421, 422 (which include a dopant). In a similar embodiment, nanoribbon 220 includes a monolayer of TMD between and coupling silicon end portions 221, 222, and the monolayer of TMD includes channel region 225 with a first dopant concentration between contact regions 421, 422, which have a second dopant concentration higher than the first dopant concentration.

In other embodiments, contact regions 421, 422 of nanoribbon 220 may be end regions of channel region 225 modified by altering a crystal phase of the channel material in contact regions 421, 422. In some embodiments, nanoribbon 220 includes a monolayer of TMD between and coupling silicon end portions 221, 222, and the monolayer of TMD includes channel region 225 in a 2H (semiconductor) crystal phase between contact regions 421, 422 in a 1T (metallic) crystal phase. The composition of the 2D (or other channel) material may be maintained while changing the structure of the material. The atomic structure change may shift the electronic configuration from semiconductor phase to metallic phase. Intercalation can be used to alter a crystal structure. In some embodiments, n-Butyllithium facilitates the intercalation of lithium into a TMD in a 2H (semiconductor) crystal phase and consequent structural transformation of the TMD into a 1T (metallic, or 1T′ semi-metallic) crystal phase. In other embodiments, such a phase change is effected by strain or heat.

Insulating sidewall spacers 215, 216 may be formed adjacent gate electrode material 245, e.g., as electrical insulation between gate electrode material 245 and source and drain terminals 211, 212.

FIG. 4Q illustrates IC die 200 with transistor structure 202 having channel regions 225 in a stack of nanoribbons 220 between source and drain terminals 211, 212 over substrate 201. Sidewall spacers 215, 216 are over sidewall spacers 213, 214, with both sets of spacers as insulators between gate electrode material 245 and source and drain terminals 211, 212. Multiple channel regions 225 are in the same or similar transistor structure 202 as described in, for example, FIG. 4P. Nanoribbons 220 span a distance 210 between terminals 211, 212. Each nanoribbon 220 includes end portions 221, 222, channel region 225, and contact regions 421, 422. Each channel region 225 is between corresponding end portions 221, 222. Each channel region 225 is between corresponding contact regions 421, 422. Each contact region 421, 422 is between a corresponding end portion 221, 222 and channel region 225. A thickness of silicon end portions 221, 222 is greater than a thickness of a corresponding channel region 225. In the example of FIG. 4Q, each channel region 225 is a crystalline TMD monolayer and includes a transition metal and a chalcogen. IC die 200 is coupled to a host component 299. IC die 200 is coupled to a power supply (not shown) through host component 299.

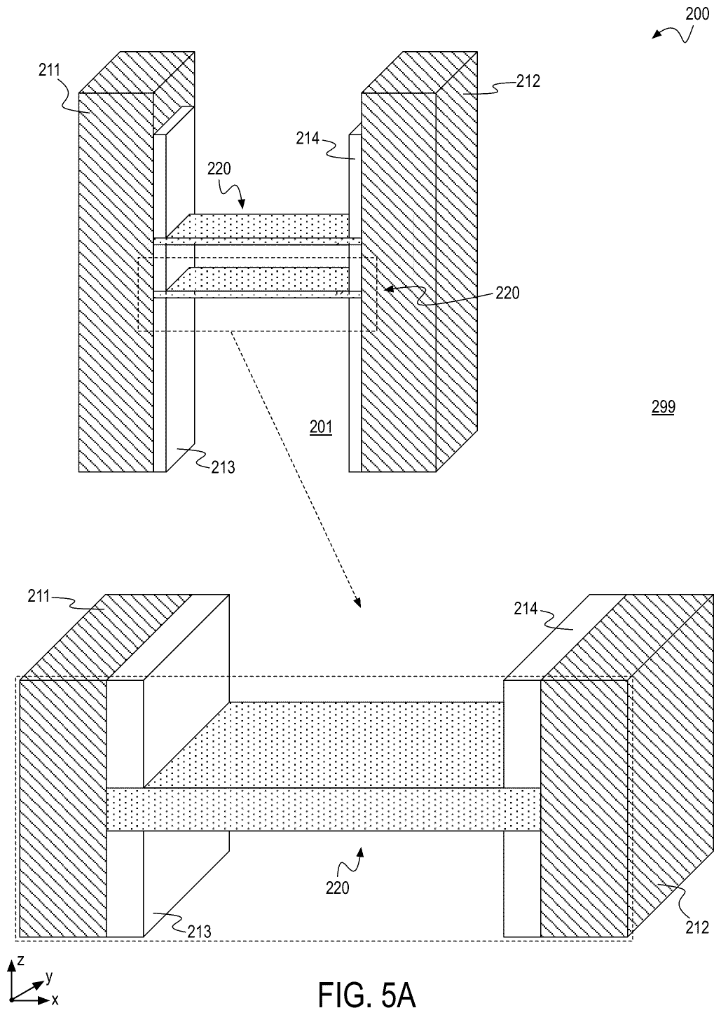

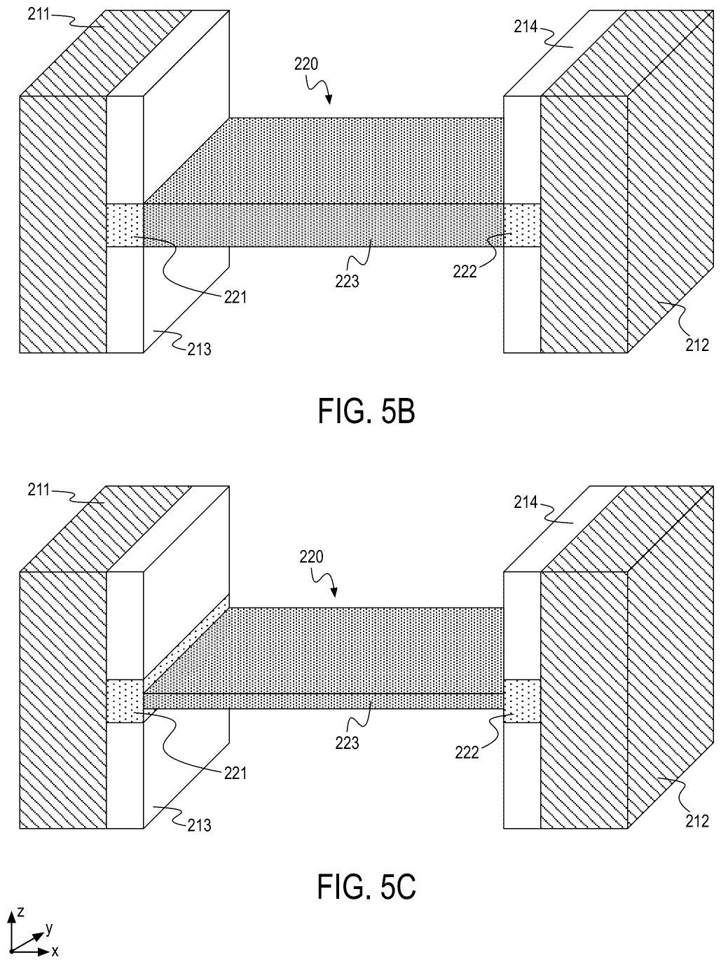

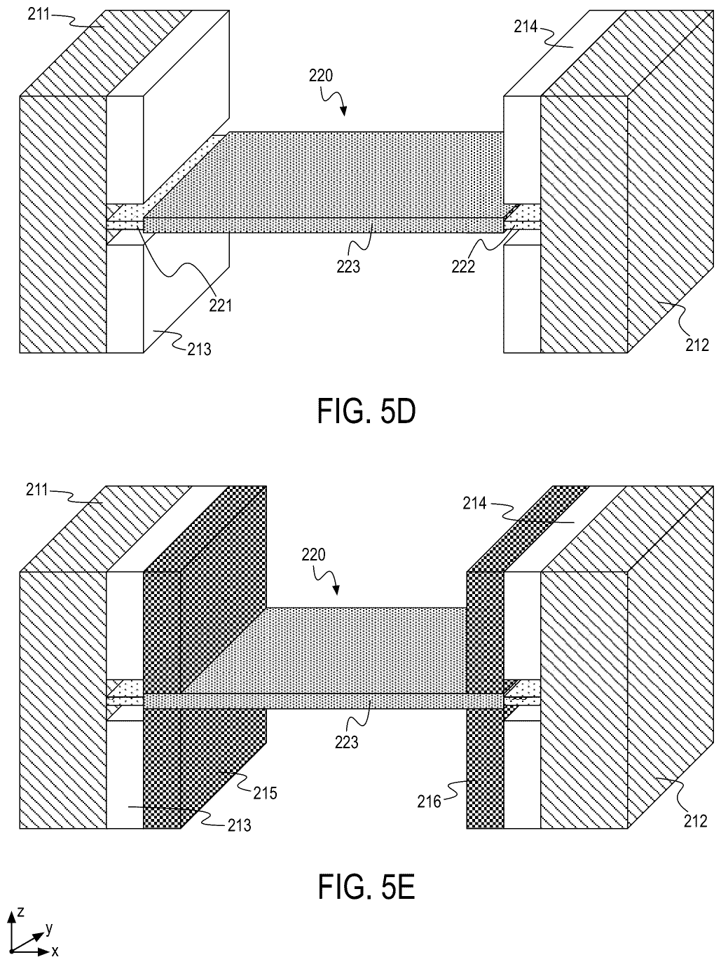

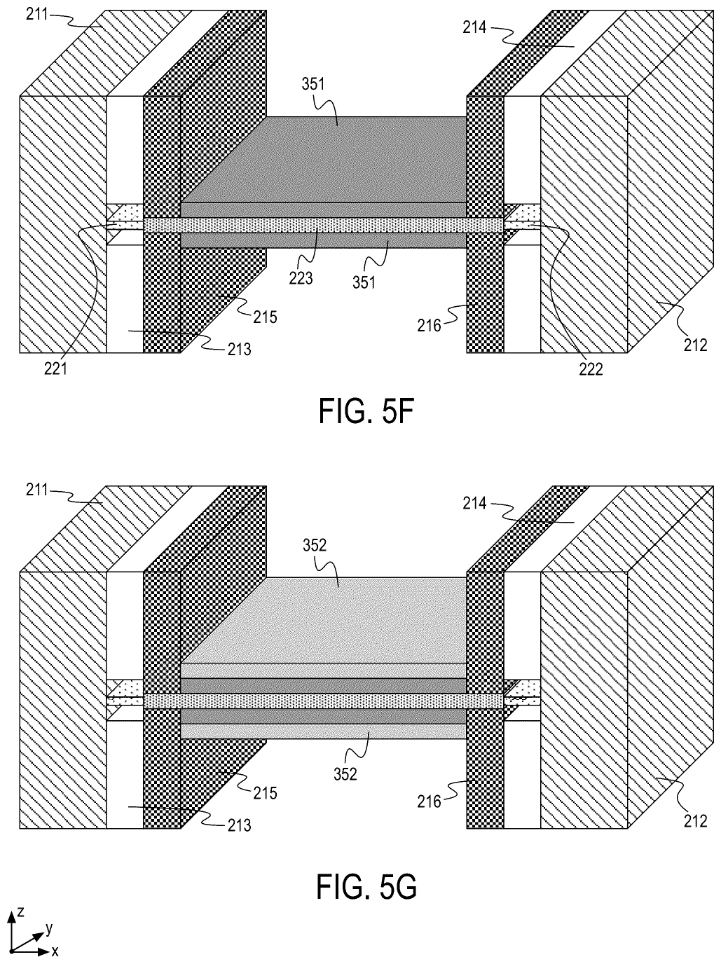

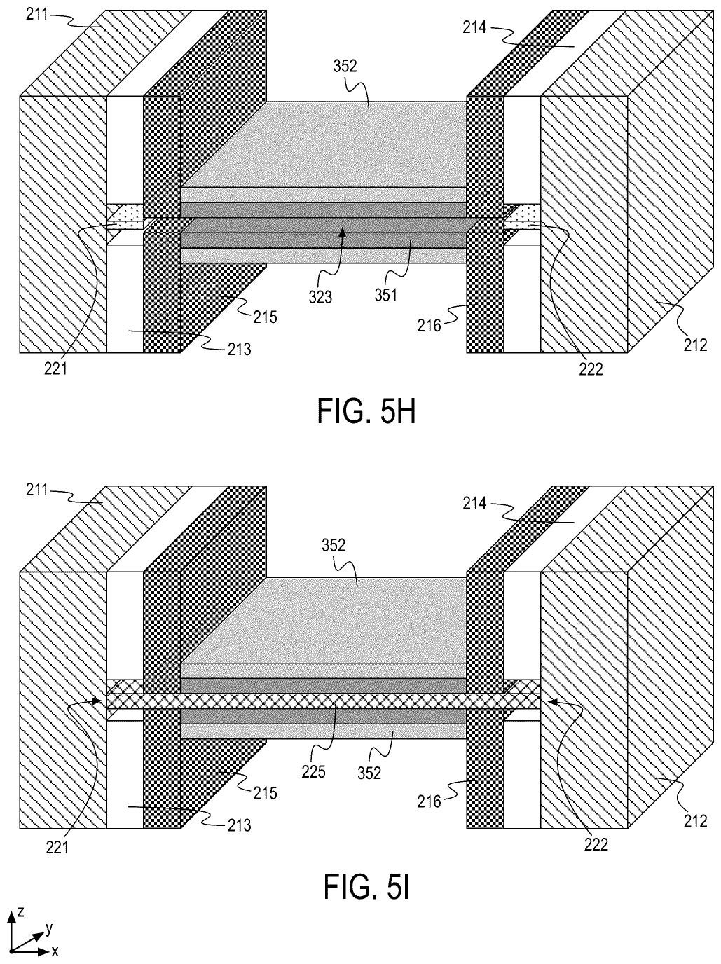

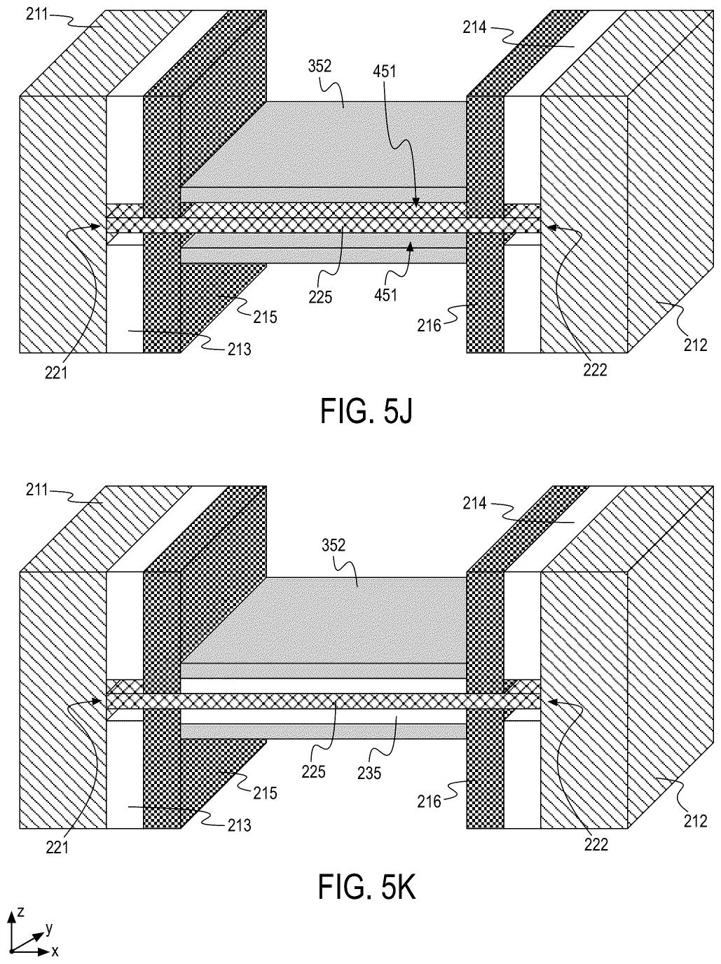

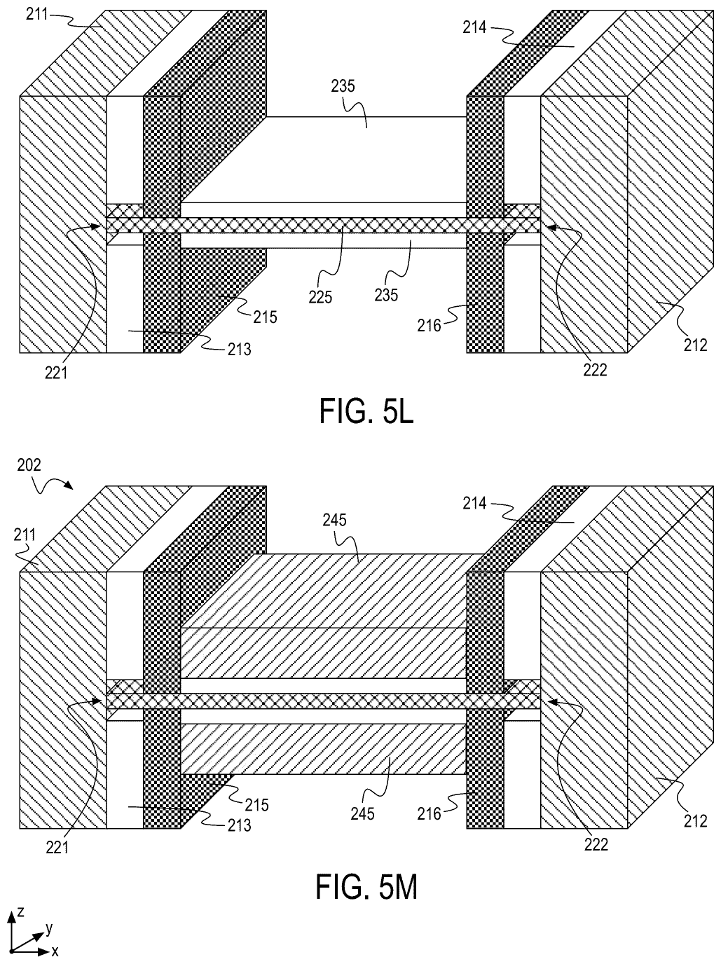

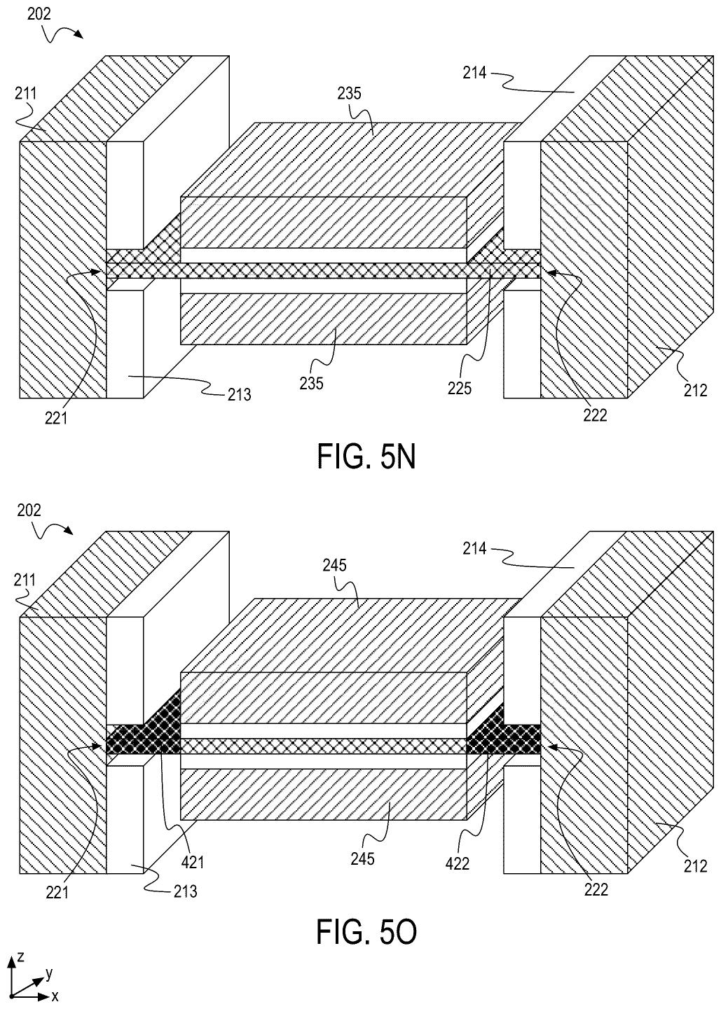

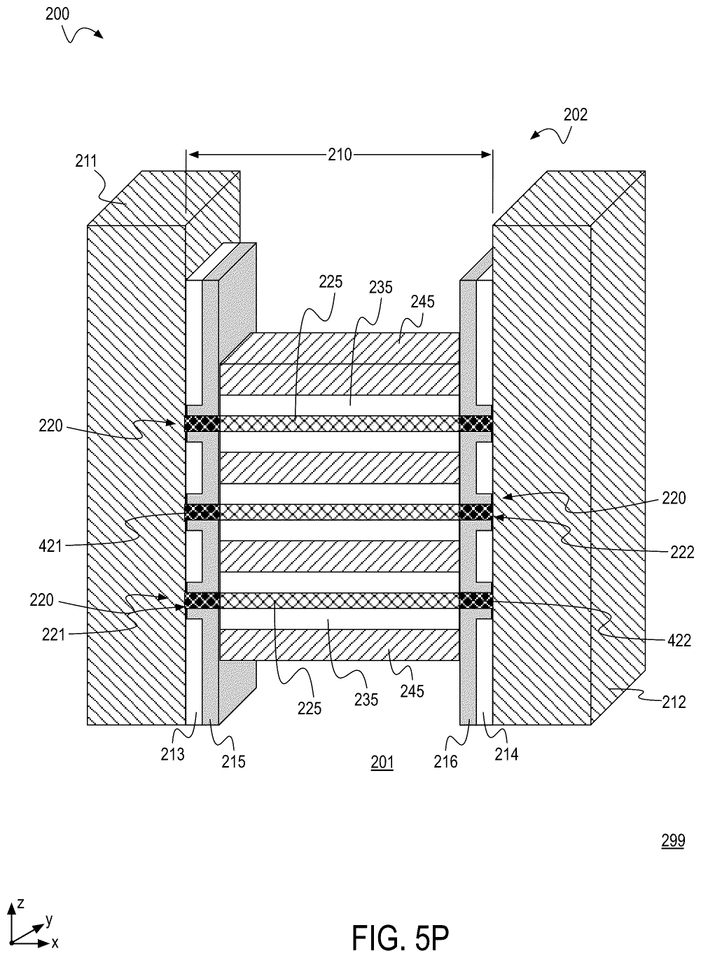

FIGS. 5A, 5B, 5C, 5D, 5E, 5F, 5G, 5H, 5I, 5J, 5K, 5L, 5M, 5N, 50, and 5P illustrate isometric views of transistor structure 202 spanning between source and drain terminals 211, 212, in accordance with some embodiments. FIGS. 5A-5P show an example progression of structures as operations of processes or methods 100 are performed. The example structures have some similarities with previous progressions shown, but the following sequence additionally illustrates optional means for growing a channel layer from a seed material at operation 130 of processes or methods 100, as well as optionally thinning an unoxidized end portion of a nanoribbon, both as will be described below.

FIG. 5A shows IC die 200 with nanoribbons 220 spanning between and coupling terminals 211, 212 over substrate 201, such as may be received at operation 110 of processes or methods 100, as previously described in, e.g., FIG. 4A. As previously described, terminals 211, 212 may include a scaffold, e.g., of silicon, of which nanoribbons 220 are a part. In the example of FIG. 5A, one or both of terminals 211, 212 may include a seed material that may act as a source for channel material during subsequent operations. In some embodiments, one or both of terminals 211, 212 includes a tungsten oxide. In some embodiments, one or both of terminals 211, 212 includes a molybdenum oxide.

FIG. 5B illustrates a magnified portion of IC die 200 with an oxidized center portion 223 between end portions 221, 222, for example, after performing an oxidizing (such as operation 120 of processes or methods 100, as previously described, e.g., in FIG. 4B).

FIG. 5C shows a thinner oxidized center portion 223 between end portions 221, 222, which have retained their previous thicknesses (much as was previously described, e.g., in FIG. 4C). Processes or methods 100 may optionally include removing an upper or lower section of oxidized center portion 223, which may expose upper or lower sections of end portions 221, 222. In some embodiments, oxidized center portion 223 is thinned to approximately 1 nm, which may allow for the flow of 2D material precursors, but confine 2D nanoribbon formation to a monolayer.

FIG. 5D illustrates end portions 221, 222 with reduced thicknesses. An upper or lower section of end portions 221, 222 may be removed, for example, by an isotropic etch selective to the material of end portions 221, 222, e.g., silicon. The removal of the material of end portions 221, 222 exposes terminals 211, 212 with a narrow opening out to, e.g., center portion 223.

FIG. 5E shows sidewall spacers 215, 216 over sidewall spacers 213, 214, masking covered portions of nanoribbon 220, much as was described in FIG. 4E. The formation of spacers 215, 216 may include the selective deposition and removal of SAM on and from oxidized center portion 223 (e.g., before and after spacer formation, as in FIGS. 4D and 4F).

FIG. 5F illustrates nanoribbon end portions 221, 222 and center portion 223 after support layer(s) 351 has been formed over exposed oxidized center portion 223 between spacers 215, 216, as was previously described, for example, in FIG. 4G.

FIG. 5G shows non-growth layer(s) 352 over support layer(s) 351, as was previously described, for example, in FIG. 4H. Non-growth layer 352 may be a sacrificial layer with an etch selectivity with support layer 351.

FIG. 5H illustrates void 323 adjacent support layer(s) 351, as was previously described, for example, in FIG. 4I. Oxidized center portion 223 is absent between support layers 351 and between end portions 221, 222. Void 323 may have the narrow vertical dimension matching that of thinned oxidized center portion 223, e.g., 1 nm, which may allow for the flow of source channel material, for example, from source terminal 211, and the lateral growth of a channel layer in void 323 and over support layer(s) 351.

FIG. 5I shows channel region 225 of nanoribbon 220 coupled to end portions 221, 222 and over and between support layer(s) 351, for example, after growing a channel layer from a seed material at operation 130 of processes or methods 100. Channel region 225 may be grown from a seed material, which may form an advantageously crystalline structure. The seed or source material (e.g., a tungsten oxide or molybdenum oxide in one or both of terminals 211, 212) may be exposed to a chalcogen-bearing precursor gas (e.g., such as a sulfide or selenide). In some embodiments, a metal (e.g., tungsten or molybdenum) from the seed or source material will react with the chalcogen and fill into void 323, growing a crystalline channel layer from the source material into void 323.

Channel region 225 is coupled to terminals 211, 212. Nanoribbon 220 includes end portions 221, 222 (not shown), which are obscured by channel region 225. Channel region 225 may be over and/or under end portions 221, 222, and end portions 221, 222 may be between channel region 225 and terminals 211, 212. Channel region 225 may appear thicker where channel region 225 is over and/or under end portions 221, 222.

FIG. 5J illustrates channel region 225 of nanoribbon 220 with support layer(s) 351 absent and void(s) 451 between channel region 225 and non-growth layer(s) 352. Support layer(s) 351 may be removed as previously described, e.g., in FIG. 4K.

FIG. 5K shows nanoribbon 220 (including end portions 221, 222 and channel region 225) with gate insulator 235 over a portion of channel region 225 and between non-growth layers 352, for example, after a deposition operation (such as operation 140 of processes or methods 100), as described in FIG. 4L. Gate insulator 235 may be of a high-k dielectric material.

FIG. 5L illustrates gate insulator 235 over a portion of channel region 225 without non-growth layer(s) 352, which may be removed by any suitable means, e.g., as described in FIG. 4M.

FIG. 5M shows transistor structure 202 with gate electrode material 245 over gate insulator 235 and channel region 225, for example, after a deposition operation (such as operation 150 of processes or methods 100) and as described in, e.g., FIG. 4N.

FIG. 5N illustrates transistor structure 202 with gate electrode material 245 and gate insulator 235 over channel region 225 and without spacers 215, 216, much as was described in FIG. 4O. With sidewall spacers 215, 216 absent, nanoribbon contact regions of channel region 225 are exposed.

FIG. 5O shows transistor structure 202 with contact regions 421, 422 of nanoribbon 220, for example, after a modification operation (such as operation 160 of processes or methods 100), as described in FIG. 4P. Contact regions 421, 422 of nanoribbon 220 are between nanoribbon end portions 221, 222 (e.g., of silicon) and channel region 225 (e.g., covered by gate insulator 235 and gate electrode material 245). Channel region 225 is between contact regions 421, 422. Channel region 225 is between end portions 221, 222. In some embodiments, contact regions 421, 422 include the same channel material as channel region 225, but additionally include a dopant, e.g., at a greater dopant concentration than a dopant concentration of channel region 225. In some embodiments, contact regions 421, 422 include the same channel material as channel region 225, but have a different crystal structure than channel region 225. For example, channel region 225 may be in a semiconductor crystal phase and contact regions 421, 422 may be in a metallic crystal phase. Portions of channel region 225 adjacent nanoribbon end portions 221, 222 may be modified by, e.g., the adding of a dopant or the altering of a crystalline phase. The crystal structure may be modified by, for example, intercalation, strain, or heat.

Insulating sidewall spacers 215, 216 may be formed adjacent gate electrode material 245, e.g., as electrical insulation between gate electrode material 245 and source and drain terminals 211, 212.

FIG. 5P illustrates IC die 200 with transistor structure 202 having channel regions 225 in a stack of nanoribbons 220 between source and drain terminals 211, 212 over substrate 201, much as described in FIG. 4Q, but with modifications included in the descriptions of FIGS. 5A-50. For example, rather than a thickness of silicon end portions 221, 222 being greater than a thickness of a corresponding channel region 225, end portions 221, 222 are obscured by contact regions 421, 422 (which have been modified from channel region 225 and which adjoin end portions 221, 222). In some embodiments, contact regions 421, 422 are over and/or under end portions 221, 222, and contact regions 421, 422 contact source and drain terminals 211, 212. In some embodiments, end portions 221, 222 are between contact regions 421, 422 and source and drain terminals 211, 212. In the example of FIG. 5P, channel regions 225 are crystalline TMD monolayers and include a transition metal and a chalcogen. IC die 200 is coupled to a host component 299. IC die 200 is coupled to a power supply (not shown) through host component 299.

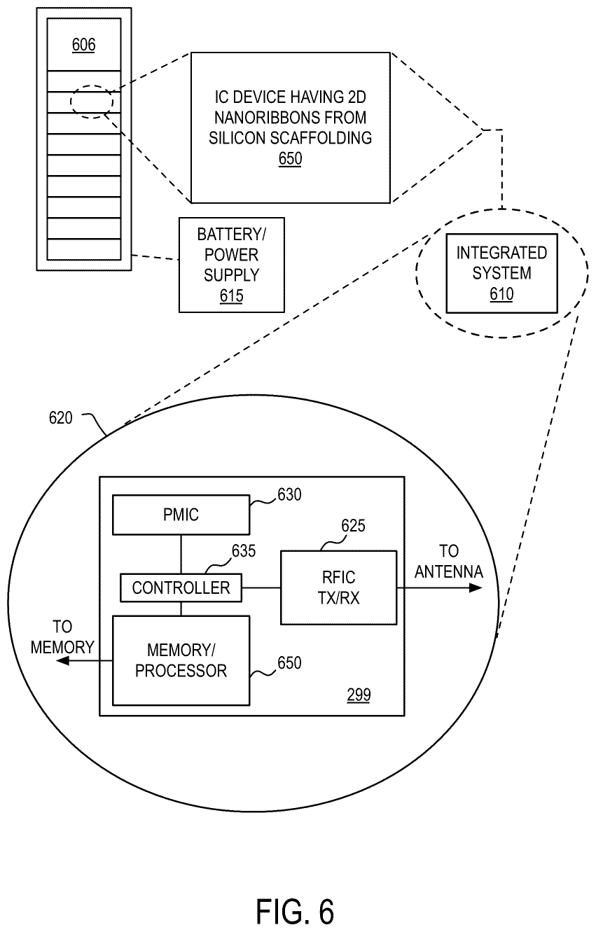

FIG. 6 illustrates a diagram of an example data server machine 606 employing an IC device having 2D nanoribbons formed from a silicon scaffold, in accordance with some embodiments. Server machine 606 may be any commercial server, for example, including any number of high-performance computing platforms disposed within a rack and networked together for electronic data processing, which in the exemplary embodiment includes one or more devices 650 having 2D nanoribbons formed from a silicon scaffold.

Also as shown, server machine 606 includes a battery and/or power supply 615 to provide power to devices 650, and to provide, in some embodiments, power delivery functions such as power regulation. Devices 650 may be deployed as part of a package-level integrated system 610. Integrated system 610 is further illustrated in the expanded view 620. In the exemplary embodiment, devices 650 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 650 is a microprocessor including a static RAM (SRAM) cache memory. As shown, device 650 may be an IC device having 2D nanoribbons formed from a silicon scaffold, as discussed herein. Device 650 may be further coupled to (e.g., communicatively coupled to) a board, an interposer, or other host component 299 along with, one or more of a power management IC (PMIC) 630, RF (wireless) IC (RFIC) 625 including a wideband RF (wireless) transmitter and/or receiver (TX/RX) (e.g., including a digital baseband and an analog front end module further includes a power amplifier on a transmit path and a low noise amplifier on a receive path), and a controller 635 thereof. In some embodiments, RFIC 625, PMIC 630, controller 635, and device 650 include 2D nanoribbons formed from a silicon scaffold.

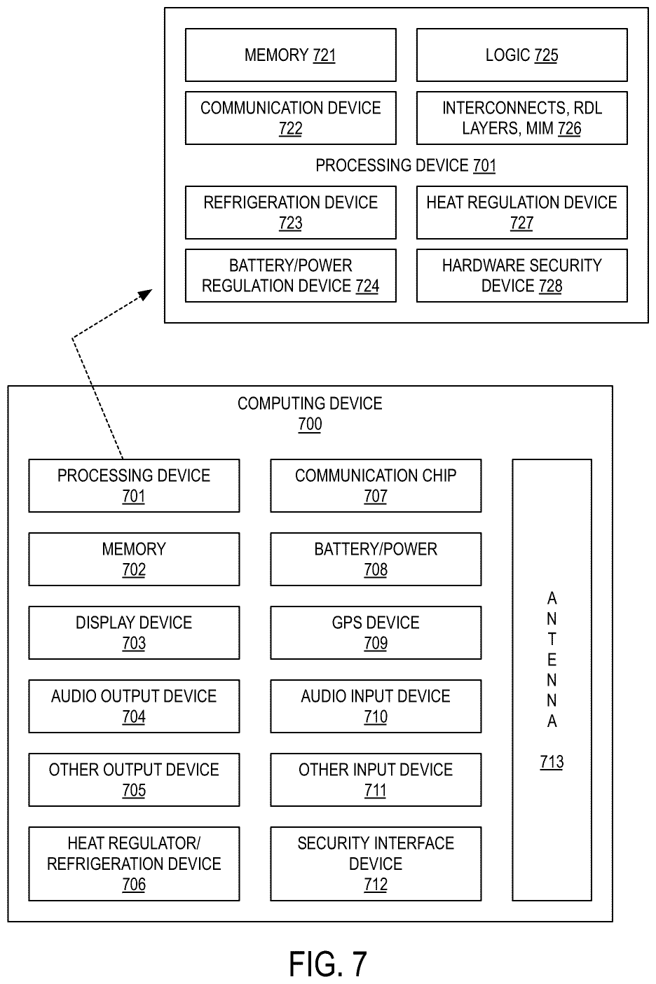

FIG. 7 is a block diagram of an example computing device 700, in accordance with some embodiments. For example, one or more components of computing device 700 may include any of the devices or structures discussed herein. A number of components are illustrated in FIG. 7 as being included in computing device 700, but any one or more of these components may be omitted or duplicated, as suitable for the application. In some embodiments, some or all of the components included in computing device 700 may be attached to one or more printed circuit boards (e.g., a motherboard). In some embodiments, various ones of these components may be fabricated onto a single system-on-a-chip (SoC) die. Additionally, in various embodiments, computing device 700 may not include one or more of the components illustrated in FIG. 7, but computing device 700 may include interface circuitry for coupling to the one or more components. For example, computing device 700 may not include a display device 703, but may include display device interface circuitry (e.g., a connector and driver circuitry) to which display device 703 may be coupled. In another set of examples, computing device 700 may not include an audio output device 704, other output device 705, global positioning system (GPS) device 709, audio input device 710, or other input device 711, but may include audio output device interface circuitry, other output device interface circuitry, GPS device interface circuitry, audio input device interface circuitry, audio input device interface circuitry, to which audio output device 704, other output device 705, GPS device 709, audio input device 710, or other input device 711 may be coupled.

Computing device 700 may include a processing device 701 (e.g., one or more processing devices). As used herein, the term “processing device” or “processor” indicates a device that processes electronic data from registers and/or memory to transform that electronic data into other electronic data that may be stored in registers and/or memory. Processing device 701 may include a memory 721, a communication device 722, a refrigeration device 723, a battery/power regulation device 724, logic 725, interconnects 726 (i.e., optionally including redistribution layers (RDL) or metal-insulator-metal (MIM) devices), a heat regulation device 727, and a hardware security device 728.

Processing device 701 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 700 may include a memory 702, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 702 includes memory that shares a die with processing device 701. This memory may be used as cache memory and may include embedded dynamic random-access memory (eDRAM) or spin transfer torque magnetic random-access memory (STT-MRAM).

Computing device 700 may include a heat regulation/refrigeration device 706. Heat regulation/refrigeration device 706 may maintain processing device 701 (and/or other components of computing device 700) at a predetermined low temperature during operation.

In some embodiments, computing device 700 may include a communication chip 707 (e.g., one or more communication chips). For example, the communication chip 707 may be configured for managing wireless communications for the transfer of data to and from computing device 700. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 707 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 707 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 707 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 707 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 707 may operate in accordance with other wireless protocols in other embodiments. Computing device 700 may include an antenna 713 to facilitate wireless communications and/or to receive other wireless communications (such as AM or FM radio transmissions).

In some embodiments, communication chip 707 may manage wired communications, such as electrical, optical, or any other suitable communication protocols (e.g., the Ethernet). As noted above, communication chip 707 may include multiple communication chips. For instance, a first communication chip 707 may be dedicated to shorter-range wireless communications such as Wi-Fi or Bluetooth, and a second communication chip 707 may be dedicated to longer-range wireless communications such as GPS, EDGE, GPRS, CDMA, WiMAX, LTE, EV-DO, or others. In some embodiments, a first communication chip 707 may be dedicated to wireless communications, and a second communication chip 707 may be dedicated to wired communications.

Computing device 700 may include battery/power circuitry 708. Battery/power circuitry 708 may include one or more energy storage devices (e.g., batteries or capacitors) and/or circuitry for coupling components of computing device 700 to an energy source separate from computing device 700 (e.g., AC line power).

Computing device 700 may include a display device 703 (or corresponding interface circuitry, as discussed above). Display device 703 may include any visual indicators, such as a heads-up display, a computer monitor, a projector, a touchscreen display, a liquid crystal display (LCD), a light-emitting diode display, or a flat panel display, for example.

Computing device 700 may include an audio output device 704 (or corresponding interface circuitry, as discussed above). Audio output device 704 may include any device that generates an audible indicator, such as speakers, headsets, or earbuds, for example.

Computing device 700 may include an audio input device 710 (or corresponding interface circuitry, as discussed above). Audio input device 710 may include any device that generates a signal representative of a sound, such as microphones, microphone arrays, or digital instruments (e.g., instruments having a musical instrument digital interface (MIDI) output).

Computing device 700 may include a GPS device 709 (or corresponding interface circuitry, as discussed above). GPS device 709 may be in communication with a satellite-based system and may receive a location of computing device 700, as known in the art.

Computing device 700 may include other output device 705 (or corresponding interface circuitry, as discussed above). Examples of the other output device 705 may include an audio codec, a video codec, a printer, a wired or wireless transmitter for providing information to other devices, or an additional storage device.

Computing device 700 may include other input device 711 (or corresponding interface circuitry, as discussed above). Examples of the other input device 711 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 700 may include a security interface device 712. Security interface device 712 may include any device that provides security measures for computing device 700 such as intrusion detection, biometric validation, security encode or decode, access list management, malware detection, or spyware detection.

Computing device 700, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-7. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, a transistor structure includes a first terminal and a second terminal, a stack of nanoribbons spanning a distance between the first and second terminals, wherein at least one nanoribbon of the stack has ends including silicon and a channel region between the ends, the channel region including a transition metal and a chalcogen, a gate electrode material between the nanoribbon and an adjacent nanoribbon of the stack, the gate electrode material spanning at least a portion of the distance between the first and second terminals, and a gate insulator between the channel region of each of the nanoribbons and the gate electrode material.

In one or more second embodiments, further to the first embodiments, the at least one nanoribbon includes first and second channel region layers, and the ends of the at least one nanoribbon include silicon in a plane between the first and second channel region layers.

In one or more third embodiments, further to the first or second embodiments, the at least one nanoribbon includes a layer including oxygen between the ends and in a plane between the first and second channel region layers.

In one or more fourth embodiments, further to the first through third embodiments, first and second contact regions of the at least one nanoribbon are between the ends, the channel region is between the first and second contact regions, and the first and second contact regions include the transition metal and the chalcogen, and further include a dopant.

In one or more fifth embodiments, further to the first through fourth embodiments, first and second contact regions of the at least one nanoribbon are between the ends, the channel region is between the first and second contact regions, the channel region has a first crystalline phase, and the first and second contact regions include the transition metal and the chalcogen in a second crystalline phase different from the first crystalline phase.

In one or more sixth embodiments, further to the first through fifth embodiments, the ends including silicon have a thickness greater than a thickness of the channel region.

In one or more seventh embodiments, further to the first through sixth embodiments, the transition metal is tungsten or molybdenum.

In one or more eighth embodiments, further to the first through seventh embodiments, the first or second terminal includes tungsten and oxygen.

In one or more ninth embodiments, an integrated circuit (IC) device includes an IC die including a substrate and a transistor over the substrate, the transistor including a first terminal and a second terminal, a stack of nanoribbons spanning a distance between the first and second terminals, wherein ends of the each of the nanoribbons include silicon and wherein a channel region of each of the nanoribbons between the ends includes a transition metal and a chalcogen, a gate electrode material between adjacent ones of the nanoribbons and spanning a portion of the distance between the first and second terminals, and a gate insulator between the channel region of each of the nanoribbons and the gate electrode material.

In one or more tenth embodiments, further to the ninth embodiments, the each of the channel regions includes the transition metal and the chalcogen in a crystalline phase.

In one or more eleventh embodiments, further to the ninth or tenth embodiments, the transition metal is tungsten or molybdenum.

In one or more twelfth embodiments, further to the ninth through eleventh embodiments, the crystalline phase of the channel regions is a first crystalline phase, the channel regions are between contact regions of the nanoribbons, and the contact regions of the nanoribbons include the transition metal and the chalcogen in a second crystalline phase different than the first crystalline phase.

In one or more thirteenth embodiments, a method includes receiving a structure including a nanoribbon spanning between a first sidewall and a second sidewall, oxidizing a first portion of the nanoribbon, wherein the first portion is between second and third portions of the nanoribbon, forming a channel layer coupled to the second and third portions, wherein the channel layer includes a transition metal and a chalcogen, depositing an insulator material over the channel layer, and depositing a gate terminal over the insulator material.

In one or more fourteenth embodiments, further to the thirteenth embodiments, forming the channel layer includes growing the channel layer from a seed material.

In one or more fifteenth embodiments, further to the thirteenth or fourteenth embodiments, forming the channel layer includes depositing the channel layer on the oxidized first portion of the nanoribbon.

In one or more sixteenth embodiments, further to the thirteenth through fifteenth embodiments, forming the channel layer includes forming a support layer over the oxidized first portion of the nanoribbon, creating a void adjacent the support layer by removing the oxidized first portion of the nanoribbon, and forming the channel layer over the support layer.

In one or more seventeenth embodiments, further to the thirteenth through sixteenth embodiments, the method also includes removing an upper or lower section of the oxidized first portion.

In one or more eighteenth embodiments, further to the thirteenth through seventeenth embodiments, the method also includes removing an upper or lower section of the second or third portions of the nanoribbon.

In one or more nineteenth embodiments, further to the thirteenth through eighteenth embodiments, the method also includes adding a dopant to a first region or a second region of the channel layer, wherein a third region is between the first and second regions.

In one or more twentieth embodiments, further to the thirteenth through nineteenth embodiments, the method also includes modifying a crystalline phase of a first region or a second region of the channel layer, wherein a third region is between the first and second regions.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. A transistor structure, comprising:
a first terminal and a second terminal;
a stack of nanoribbons spanning a distance between the first and second terminals, wherein at least one nanoribbon of the stack has ends comprising silicon and a channel region between the ends, the channel region comprising a transition metal and a chalcogen;
a gate electrode material between the nanoribbon and an adjacent nanoribbon of the stack, the gate electrode material spanning at least a portion of the distance between the first and second terminals; and
a gate insulator between the channel region of each of the nanoribbons and the gate electrode material.

2. The transistor structure of claim 1, wherein the at least one nanoribbon comprises first and second channel region layers, and the ends of the at least one nanoribbon comprise silicon in a plane between the first and second channel region layers.

3. The transistor structure of claim 2, wherein the at least one nanoribbon comprises a layer comprising oxygen between the ends and in a plane between the first and second channel region layers.

4. The transistor structure of claim 1, wherein first and second contact regions of the at least one nanoribbon are between the ends, the channel region is between the first and second contact regions, and the first and second contact regions comprise the transition metal and the chalcogen, and further comprise a dopant.

5. The transistor structure of claim 1, wherein first and second contact regions of the at least one nanoribbon are between the ends, the channel region is between the first and second contact regions, the channel region has a first crystalline phase, and the first and second contact regions comprise the transition metal and the chalcogen in a second crystalline phase different from the first crystalline phase.

6. The transistor structure of claim 1, wherein the ends comprising silicon have a thickness greater than a thickness of the channel region.

7. The transistor structure of claim 1, wherein the transition metal is tungsten or molybdenum.

8. The transistor structure of claim 1, wherein the first or second terminal comprises tungsten and oxygen.

9. An integrated circuit (IC) device, comprising:
an IC die comprising a substrate and a transistor over the substrate, the transistor comprising:
a first terminal and a second terminal;
a stack of nanoribbons spanning a distance between the first and second terminals, wherein ends of the each of the nanoribbons comprise silicon and wherein a channel region of each of the nanoribbons between the ends comprises a transition metal and a chalcogen;
a gate electrode material between adjacent ones of the nanoribbons and spanning a portion of the distance between the first and second terminals; and
a gate insulator between the channel region of each of the nanoribbons and the gate electrode material.

10. The IC device of claim 9, wherein the each of the channel regions comprises the transition metal and the chalcogen in a crystalline phase.

11. The IC device of claim 10, wherein the transition metal is tungsten or molybdenum.

12. The IC device of claim 10, wherein the crystalline phase of the channel regions is a first crystalline phase, the channel regions are between contact regions of the nanoribbons, and the contact regions of the nanoribbons comprise the transition metal and the chalcogen in a second crystalline phase different than the first crystalline phase.

13. A method, comprising:
receiving a structure comprising a nanoribbon spanning between a first sidewall and a second sidewall;
oxidizing a first portion of the nanoribbon, wherein the first portion is between second and third portions of the nanoribbon;
forming a channel layer coupled to the second and third portions, wherein the channel layer comprises a transition metal and a chalcogen;
depositing an insulator material over the channel layer; and
depositing a gate terminal over the insulator material.

14. The method of claim 13, wherein forming the channel layer comprises growing the channel layer from a seed material.

15. The method of claim 13, wherein forming the channel layer comprises depositing the channel layer on the oxidized first portion of the nanoribbon.

16. The method of claim 13, wherein forming the channel layer comprises:
forming a support layer over the oxidized first portion of the nanoribbon;
creating a void adjacent the support layer by removing the oxidized first portion of the nanoribbon; and
forming the channel layer over the support layer.

17. The method of claim 13, further comprising removing an upper or lower section of the oxidized first portion.

18. The method of claim 13, further comprising removing an upper or lower section of the second or third portions of the nanoribbon.

19. The method of claim 13, further comprising adding a dopant to a first region or a second region of the channel layer, wherein a third region is between the first and second regions.

20. The method of claim 13, further comprising modifying a crystalline phase of a first region or a second region of the channel layer, wherein a third region is between the first and second regions.
